(19) United States
(12) Patent Application Publication
(10) Pub. No.: US 2014/0346406 A1
(43) Pub. Date: Nov. 27, 2014

(54) ORGANIC ELECTROLUMINESCENT DEVICE COMPRISING THE ORGANIC ELECTROLUMINESCENT COMPOUNDS

(71) Applicant: Rohm and Haas Electronic Materials Korea Ltd., Chungcheongnam-do (KR)

(72) Inventors: Hyo-Jung Lee, Gyeonggi-do (KR); Young-Gil Kim, Gyeonggi-do (KR); Hyo-Nim Shin, Gyeonggi-do (KR); Kyung-Joo Lee, Seoul (KR); Young-Jun Cho, Gyeonggi-do (KR); Hyuck-Joo Kwon, Seoul (KR); Bong-Ok Kim, Seoul (KR)

(21) Appl. No.: 14/372,749

(22) PCT Filed: Jan. 15, 2013
(86) PCT No.: PCT/KR2013/000297

§ 371 Date: Jul. 16, 2014

(30) Foreign Application Priority Data
Jan. 16, 2012 (KR) 10-2012-0004831

(51) Int. Cl. H01L 51/00

(52) U.S. Cl. CPC H01L 51/0054; H01L 51/0058; H01L 51/0067; H01L 51/0094; H01L 51/0074; H01L 51/0073; H01L 51/0072; H01L 51/006; H01L 51/0061; H01L 51/5012
USPC 252/500

(57) ABSTRACT

The present invention relates to an organic electroluminescent device comprising a combination of specific host compounds and specific dopant compounds. The organic electroluminescent device according to the present invention shows a blue emission; and has a long operating lifespan, high efficiency, high brightness, good color purity, low driving voltage, and improved operational stability.

### TECHNICAL FIELD

The present invention relates to an organic electroluminescent device comprising specific dopant compounds and specific host compounds.

### BACKGROUND ART

An electroluminescent (EL) device is a self-light-emitting device with advantages in that it provides a wider viewing angle, a greater contrast ratio, and a faster response time compared with LCD. An organic EL device was first developed by Eastman Kodak, by using small aromatic diamine molecules, and aluminum complexes as materials for forming a light-emitting layer [Appl. Phys. Lett. 51, 913, 1987].

The organic EL device emits a light by the injection of a charge into an organic film formed between an electron injection electrode (cathode) and a hole injection electrode (anode) and by extinction of a pair of the electron and the hole. The organic EL device has advantages as follows: it can be formed onto a flexible transparent substrate, such as a plastic; can be driven at a lower voltage, for example, 10 V or less, over a plasma display panel or an inorganic EL display; has relatively low power consumption; and provides good color. Further, the organic EL device provides tricolor light-emitting, i.e., green, blue or red light-emitting, and thus there is interest from many people as a next generation color display device.

The preparation process of an organic EL device can be briefly summarized as follows:

(1) An anodic material is coated onto a transparent substrate. ITO (indium tin oxide) is commonly used as an anodic material.

(2) A hole injection layer (HIL) is coated onto the anodic material layer. As the HIL, for example, copper phthalocyanine (CuPc) is commonly coated in a thickness of 10 nm to 30 nm.

(3) A hole transport layer (HTL) is applied onto the HIL layer. As the HTL, 4,4′-bis[N-(1-naphthyl)-N-phenylamino]-biphenyl (NPB), for example, is vapor deposited in a thickness of 30 nm to 60 nm.

(4) An organic emitting layer is coated onto the HTL layer, while adding a dopant, if needed. In case of green light-emitting, tris(8-hydroxyquinolate)aluminum (Alq₃) is commonly vapor deposited in a thickness of 30 nm to 60 nm as the organic emitting layer, and N-methylquinacridone (MQD) is used as a dopant.

(5) An electron transport layer (ETL) and an electron injection layer (EIL) are continuously coated or an electron injection-transport layer is coated onto the organic emitting layer. In case of green light-emitting, additional EIL and ETL may not be used, since Alq₃ in step (4) has good electron transport capacity.

(6) A cathodic material is coated onto the layer formed in step (5). Subsequently, a protection layer is finally coated.

The green, blue or red light-emitting device can be prepared depending on how a light-emitting layer is formed in the device structure. Meanwhile, a light-emitting material used as a green light-emitting compound in a conventional green light-emitting device has disadvantages in terms of lifespan and luminescent efficiency.

The most important factor determining properties, such as luminescent efficiency, lifespan, etc., is a light-emitting material in an organic EL device. The light-emitting material is required to have the following features: high fluorescence quantum yield in a solid state, high movement degree of an electron and a hole, non-breakdown in vacuum deposition, formability of a uniform thin film, and stability.

An organic light-emitting material can be largely divided into a high molecular material and a low molecular material. The low molecular material is a pure organic light-emitting material in view of a molecular structure, which does not contain metal complexes and metals. As said light-emitting material, a chelate complex, such as tris(8-quinolinolato)aluminum complex, coumarin derivatives, tetraphenylbutadiene derivatives, bistyrylarylene derivatives, oxadiazole derivatives, etc., were known. It was reported that visible region light-emitting from blue to red light-emitting can be obtained from said materials.

However, when a light-emitting material comprising conventional dopant compounds and host compounds is used in an organic electroluminescent device, the device did not provide high current efficiency and satisfactory operating lifespan, and had a problem in luminescent efficiency. Further, it was difficult to achieve a blue light-emitting material having excellent properties.

### DISCLOSURE OF INVENTION

### Technical Problem

The present inventors exerted to solve said problems and found that the light-emitting material comprising a combination of specific dopant compounds and specific host compounds exhibits a blue emission and is suitable for preparing an organic electroluminescent device having high color purity, high brightness, and a long lifespan.

The object of the present invention is to provide an organic electroluminescent device having high luminescent efficiency, excellent color purity, low driving voltage, and a long operating lifespan.

### Solution to Problem

In order to achieve said object, the present invention provides an organic electroluminescent device, comprising a combination of at least one host compound represented by the following formula 1 and at least one dopant compound represented by the following formula 2:

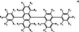

wherein

R₁ to R₂₄ each independently represent hydrogen, deuterium, a halogen, a substituted or unsubstituted (C1-C30)alkyl group, a substituted or unsubstituted (C1-C30)alkoxy group, a substituted or unsubstituted (C6-C30)aryl group, a substituted or unsubstituted 3- to 30-membered heteroaryl group, —SiR₃₁R₃₂R₃₃, a cyano group or a hydroxyl group; or R₂₀ to R₂₄ are linked each other to form a substituted or unsubstituted mono- or polycyclic, 3- to 30-membered alicyclic or aromatic ring whose carbon atom(s) may be replaced with at least one hetero atom selected from nitrogen, oxygen and sulfur;

R₃₁ to R₃₃ each independently represent hydrogen, deuterium, a halogen, a substituted or unsubstituted (C1-C30)alkyl group, a substituted or unsubstituted (C6-C30)aryl group, or a substituted or unsubstituted 3- to 30-membered heteroaryl group; and

the heteroaryl group contains at least one hetero atom selected from the group consisting of B, N, O, S, P(═O), Si and P.

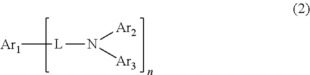

wherein

Ar₁ represents a substituted or unsubstituted pyrene ring, or a substituted or unsubstituted chrycene ring;

L represents a single bond, a substituted or unsubstituted (C6-C30)aryl group, or a substituted or unsubstituted 3- to 30-membered heteroaryl group;

Ar₂ and Ar₃ each independently represent hydrogen, deuterium, a halogen, a substituted or unsubstituted (C1-C30)alkyl group, a substituted or unsubstituted (C6-C30)aryl group, or a substituted or unsubstituted 3- to 30-membered heteroaryl group; or are linked with an adjacent substituent(s) to form a substituted or unsubstituted mono- or polycyclic, 3- to 30-membered alicyclic or aromatic ring whose carbon atom(s) may be replaced with at least one hetero atom selected from nitrogen, oxygen and sulfur;

n represents an integer of 1 to 2; where n is an integer of 2, the structural units within the square brackets are the same or different; and

the heteroaryl group contains at least one hetero atom selected from the group consisting of B, N, O, S, P(═O), Si and P.

Preferably, in formula 1, R₁ to R₂₄ each independently represent hydrogen, deuterium, fluorine, a substituted or unsubstituted (C1-C10)alkyl group, a substituted or unsubstituted (C1-C10)alkoxy group, a substituted or unsubstituted (C6-C15)aryl group, a substituted or unsubstituted 3- to 15-membered heteroaryl group, —SiR₃₁R₃₂R₃₃, a cyano group or a hydroxyl group; or R₂₀ to R₂₄ are linked together to form a substituted or unsubstituted mono- or polycyclic, 3- to 30-membered alicyclic or aromatic ring whose carbon atom(s) may be replaced with at least one hetero atom selected from nitrogen, oxygen and sulfur; and R₃₁ to R₃₃ each independently represent an unsubstituted (C1-C10)alkyl group or an unsubstituted (C6-C15)aryl group.

Preferably, in formula 2, L represents a single bond or an unsubstituted (C6-C15)aryl group; and Ar₂ and Ar₃ each independently represent a substituted or unsubstituted (C6-C15)aryl group, or are linked with an adjacent substituent(s) to form a substituted or unsubstituted mono- or polycyclic, 3- to 15-membered alicyclic or aromatic ring whose carbon atom(s) may be replaced with at least one hetero atom selected from nitrogen, oxygen and sulfur.

### Advantageous Effects of Invention

The organic electroluminescent device according to the present invention has high luminescent efficiency, a long operating lifespan, high brightness, good color purity, low driving voltage, and enhanced current efficiency.

### MODE FOR THE INVENTION

Hereinafter, the present invention will be described in detail. However, the following description is intended to explain the invention, and is not meant in any way to restrict the scope of the invention.

Herein, “(C1-C30)alkyl” is meant to be a linear or branched alkyl having 1 to 30 carbon atoms, in which the number of carbon atoms is preferably 1 to 10, and includes methyl, ethyl, n-propyl, isopropyl, n-butyl, isobutyl, tert-butyl, etc. “(C3-C30)cycloalkyl” is a mono- or polycyclic hydrocarbon having 3 to 30 carbon atoms, in which the number of carbon atoms is preferably 3 to 20, more preferably 3 to 7, and includes cyclopropyl, cyclobutyl, cyclopentyl, cyclohexyl, etc. “(C6-C30)aryl” is a monocyclic or fused ring derived from an aromatic hydrocarbon having 6 to 30 carbon atoms, in which the number of carbon atoms is preferably 6 to 15, and includes phenyl, biphenyl, terphenyl, naphthyl, fluorenyl, phenanthrenyl, anthracenyl, indenyl, triphenylenyl, pyrenyl, tetracenyl, perylenyl, chrycenyl, naphthacenyl, fluoranthenyl, etc. “3- to 30-membered heteroaryl” is an aryl group having at least one, preferably 1 to 4 hetero atom(s) selected from the group consisting of B, N, O, S, P(═O), Si and P, and 3 to 30 ring backbone atoms; is a monocyclic ring, or a fused ring condensed with at least one benzene ring; has preferably 5 to 15 ring backbone atoms; may be partially saturated; may be one formed by linking at least one heteroaryl or aryl group to a heteroaryl group via a single bond(s); and includes a monocyclic ring-type heteroaryl such as furyl, thiophenyl, pyrrolyl, imidazolyl, pyrazolyl, thiazolyl, thiadiazolyl, isothiazolyl, isoxazolyl, oxazolyl, oxadiazolyl, triazinyl, tetrazinyl, triazolyl, tetrazolyl, furazanyl, pyridyl, pyrazinyl, pyrimidinyl, pyridazinyl, etc., and a fused ring-type heteroaryl such as benzofuranyl, benzothiophenyl, isobenzofuranyl, dibenzofuranyl, dibenzothiophenyl, benzoimidazolyl, benzothiazolyl, benzoisothiazolyl, benzoisoxazolyl, benzoxazolyl, isoindolyl, indolyl, indazolyl, benzothiadiazolyl, quinolyl, isoquinolyl, cinnolinyl, quinazolinyl, quinoxalinyl, carbazolyl, phenoxazinyl, phenanthridinyl, benzodioxolyl, etc. Further, “Halogen” includes F, Cl, Br and I.

Herein, “substituted” in the expression “substituted or unsubstituted” means that a hydrogen atom in a certain functional group is replaced with another atom or group, i.e., a substituent. Substituents of the substituted (C1-C30)alkyl group, the substituted (C1-C30)alkoxy group, the substituted (C6-C30)aryl group, the substituted 3- to 30-membered heteroaryl group, and the substituted mono- or polycyclic, 3- to 30-membered alicyclic or aromatic ring in R₁ to R₂₄, R₃₁ to R₃₃, L, and Ar₁ to Ar₃ groups of formulae 1 and 2 are independently at least one selected from the group consisting of deuterium; a halogen; a (C1-C30)alkyl group; a halo(C1-C30)alkyl group; a (C1-C30)alkoxy group; a (C6-C30)aryloxy group; a (C6-C30)aryl group; a 3- to 30-membered heteroaryl group; a 3- to 30-membered heteroaryl group substituted with a (C6-C30)aryl group; a (C6-C30)aryl group substituted with a 3- to 30-membered heteroaryl group; a (C3-C30)cycloalkyl group; a 5- to 7-membered heterocycloalkyl group; a tri(C1-C30)alkylsilyl group; a tri(C6-C30)arylsilyl group; a di(C1-C30)alkyl(C6-C30)arylsilyl group; a (C1-C30)alkyldi(C6-C30)arylsilyl group; a (C2-C30)alkenyl group; a (C2-C30)alkynyl group; a cyano group; a (C1-C30)alkylthio group; a (C6-C30)arylthio group; an N-carbazolyl group; a mono- or di(C1-C30)alkylamino group; a mono- or di(C6-C30)arylamino group; a (C1-C30)alkyl(C6-C30)arylamino group; a di(C6-C30)arylboronyl group; a di(C1-C30)alkylboronyl group; a (C1-C30)alkyl(C6-C30)arylboronyl group; a (C6-C30)aryl(C1-C30)alkyl group; a (C1-C30)alkyl(C6-C30)aryl group; a carboxyl group; a nitro group; and a hydroxyl group.

The organic electroluminescent device according to the present invention has an efficient energy transport mechanism between hosts and dopants, and thus can achieve high efficiency luminescence based on the effect of improved electron density distribution. Further, the device can overcome the disadvantages found in conventional material, such as reduced initial efficiency, a short operating lifespan, etc., and can achieve high luminescent efficiency and a long operating lifespan for each color.

The Ar₁ of formula 2 can be selected from the group consisting of the following structures, but is not limited thereto:

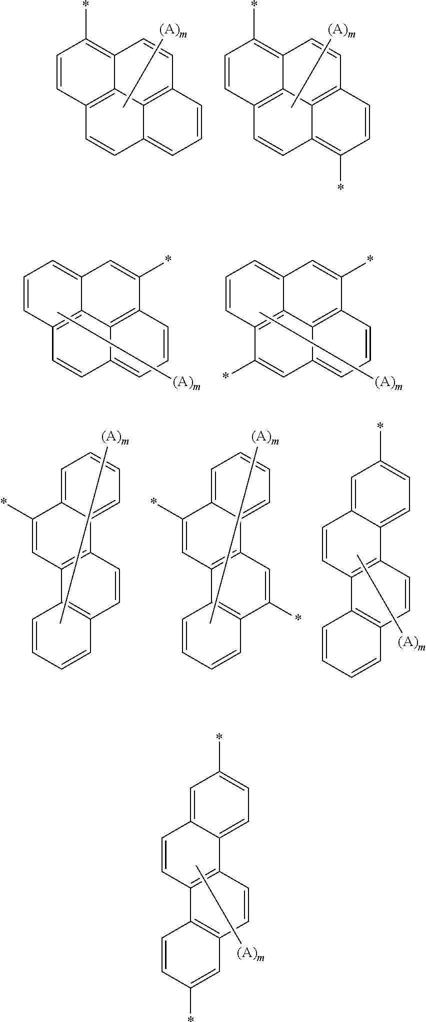

wherein

A represents deuterium, a halogen, a (C1-C30)alkyl group, a halo(C1-C30)alkyl group, a (C6-C30)aryl group, a 3- to 30-membered heteroaryl group, a 3- to 30-membered heteroaryl group substituted with a (C6-C30)aryl group, a (C6-C30)aryl group substituted with a 3- to 30-membered heteroaryl group; a (C3-C30)cycloalkyl group; a 5- to 7-membered heterocycloalkyl group; a tri(C1-C30)alkylsilyl group; a tri(C6-C30)arylsilyl group; a di(C1-C30)alkyl(C6-C30)arylsilyl group; a (C1-C30)alkyldi(C6-C30)arylsilyl group; a (C2-C30)alkenyl group; a (C2-C30)alkynyl group; a cyano group; an N-carbazolyl group; a di(C1-C30)alkylamino group; a di(C6-C30)arylamino group; a (C1-C30)alkyl(C6-C30)arylamino group; a di(C6-C30)arylboronyl group; a di(C1-C30)alkylboronyl group; a (C1-C30)alkyl(C6-C30)arylboronyl group; a (C6-C30)aryl(C1-C30)alkyl group; a (C1-C30)alkyl(C6-C30)aryl group; a carboxyl group; a nitro group; and a hydroxyl group; and

m represents an integer of 0 to 4.

The host compounds of formula 1 can be specifically exemplified as the following compounds, but are not limited thereto:

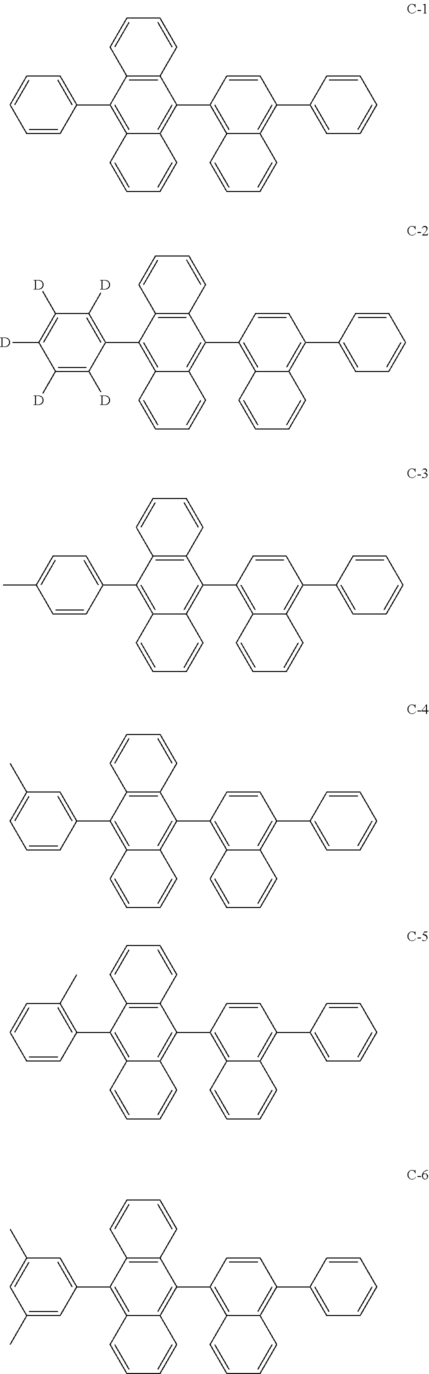

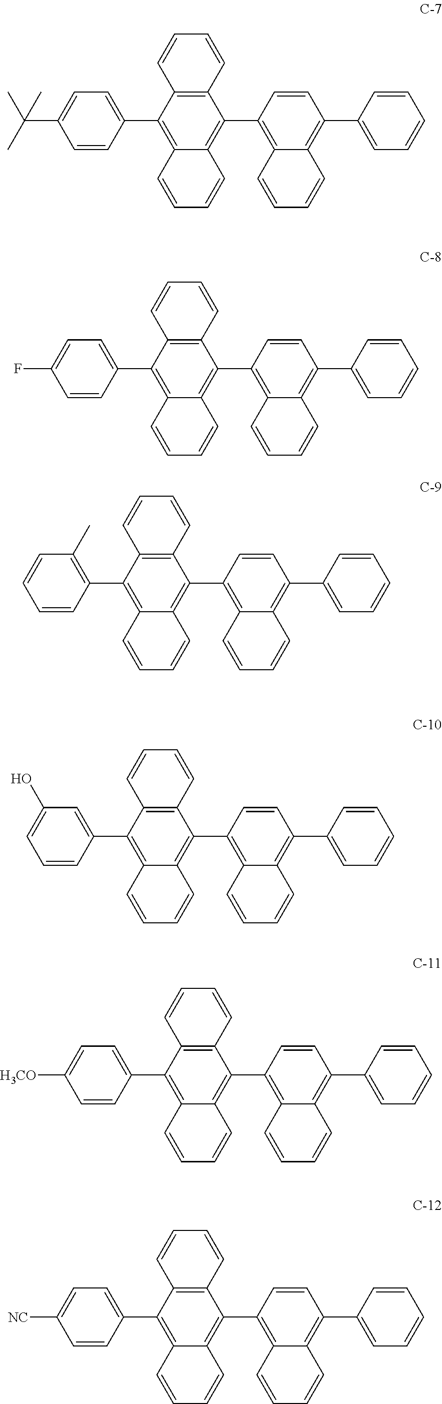

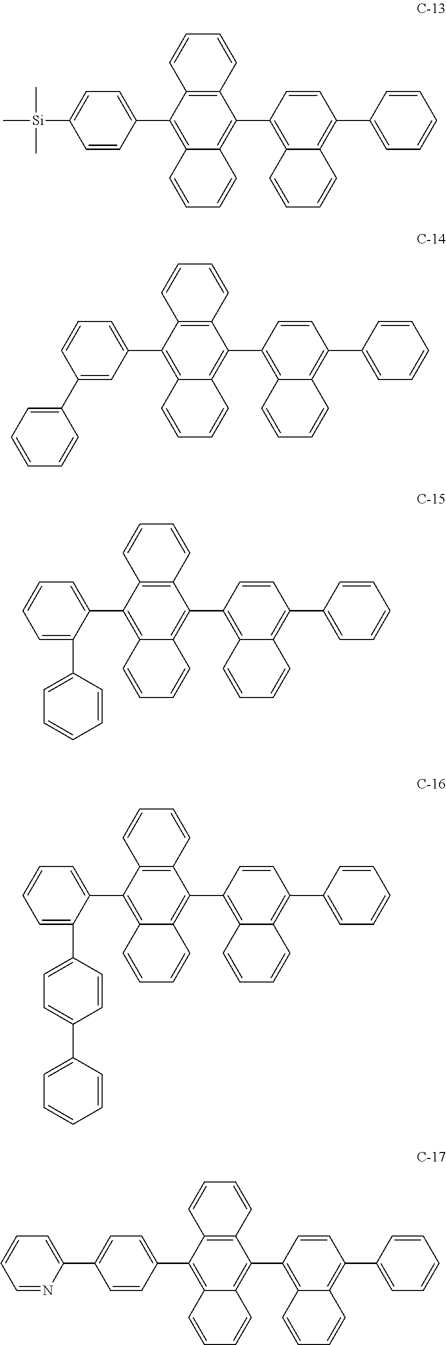

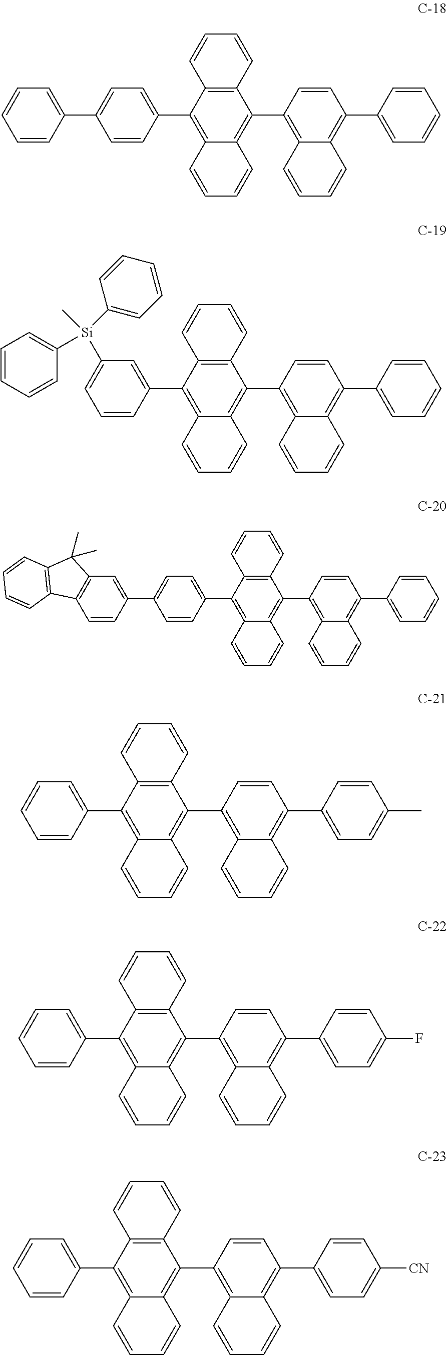

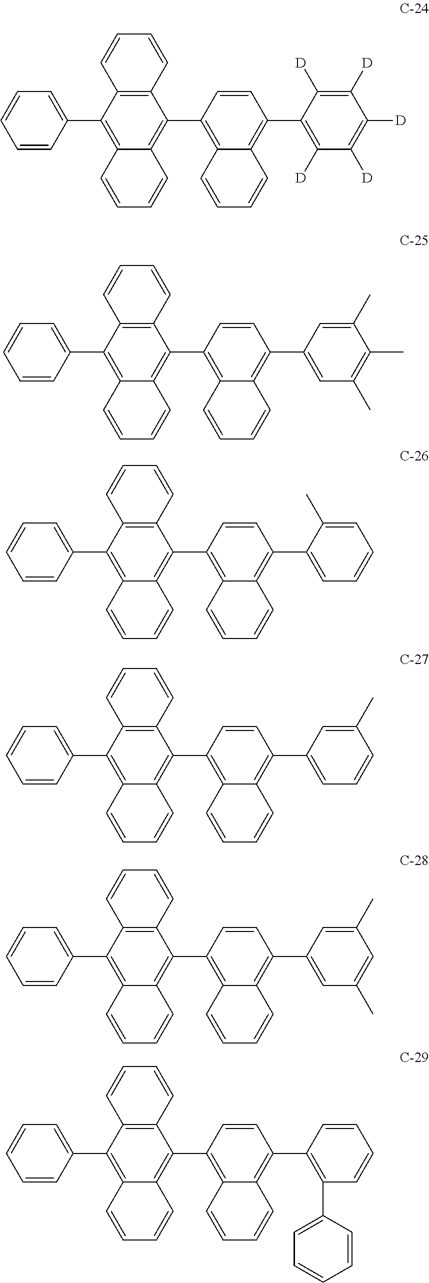

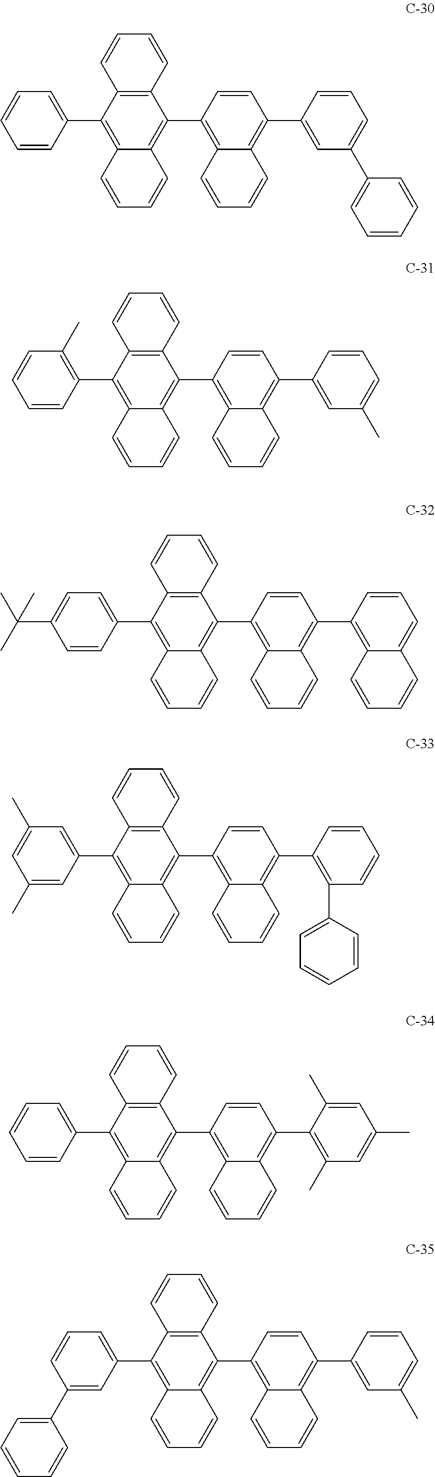

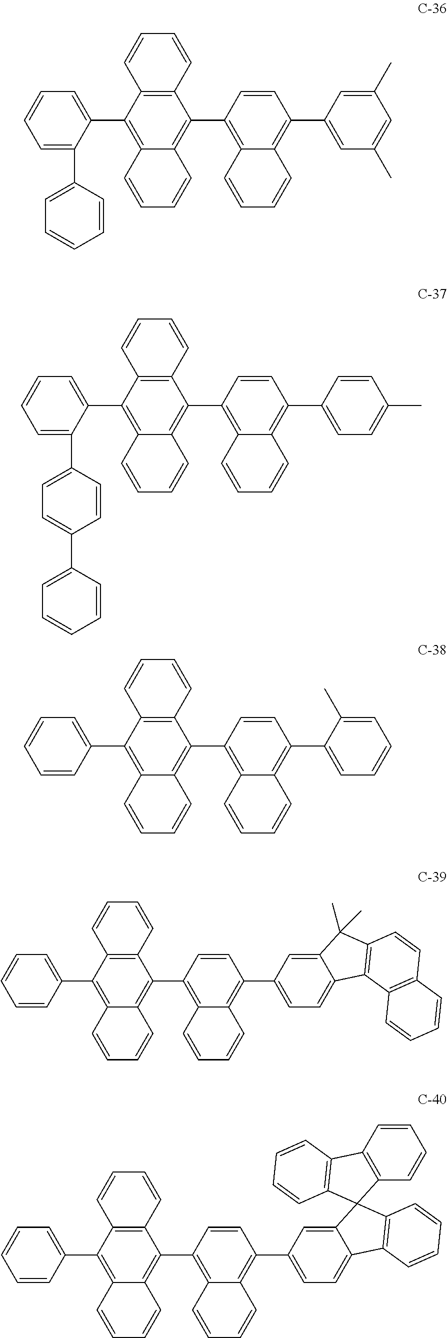

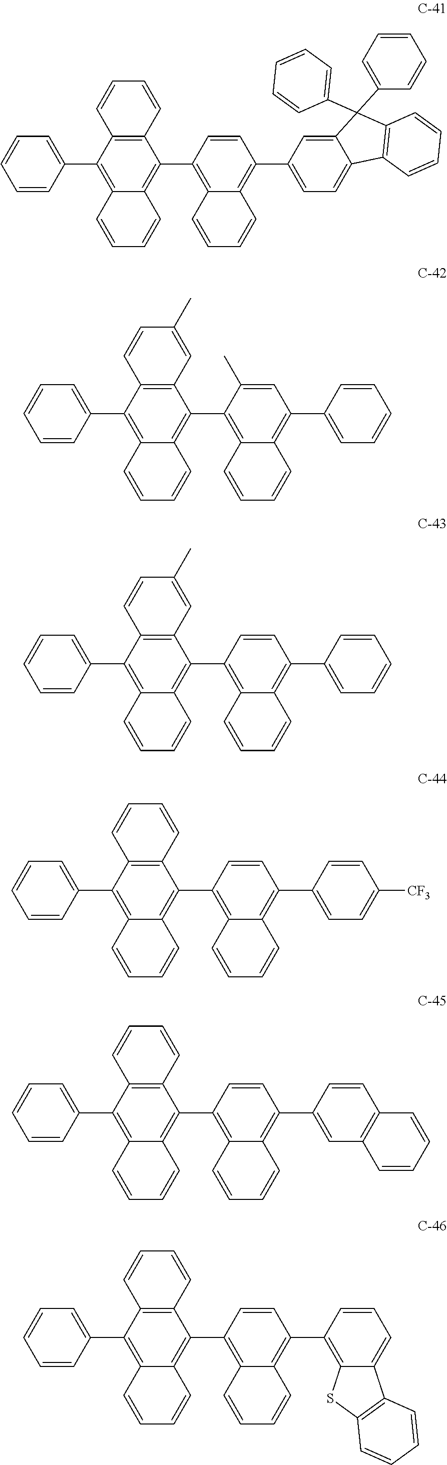

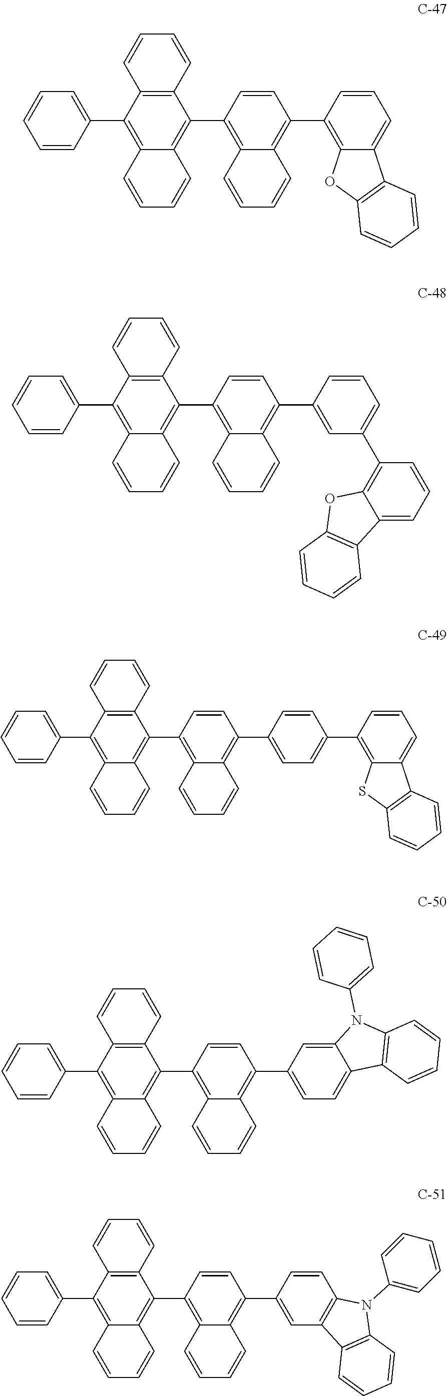 [SMILES: c1ccc(-c2c3ccccc3c(-c3ccc(-c4cccc5c4oc4ccccc45)c4ccccc34)c3ccccc23)cc1 ; c1ccc(-c2c3ccccc3c(-c3ccc(-c4cccc(-c5cccc6c5oc5ccccc56)c4)c4ccccc34)c3ccccc23)cc1 ; c1ccc(-c2c3ccccc3c(-c3ccc(-c4ccc(-c5cccc6c5sc5ccccc56)cc4)c4ccccc34)c3ccccc23)cc1 ; c1ccc(-c2c3ccccc3c(-c3ccc(-c4ccc5c6ccccc6n(-c6ccccc6)c5c4)c4ccccc34)c3ccccc23)cc1 ; c1ccc(-c2c3ccccc3c(-c3ccc(-c4ccc5c(c4)c4ccccc4n5-c4ccccc4)c4ccccc34)c3ccccc23)cc1]

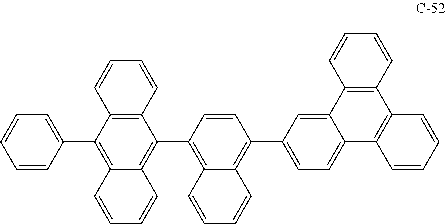 [SMILES: c1ccc(-c2c3ccccc3c(-c3ccc(-c4ccc5c6ccccc6c6ccccc6c5c4)c4ccccc34)c3ccccc23)cc1]

Further, the dopant compounds of formula 2 can be specifically exemplified as the following compounds, but are not limited thereto:

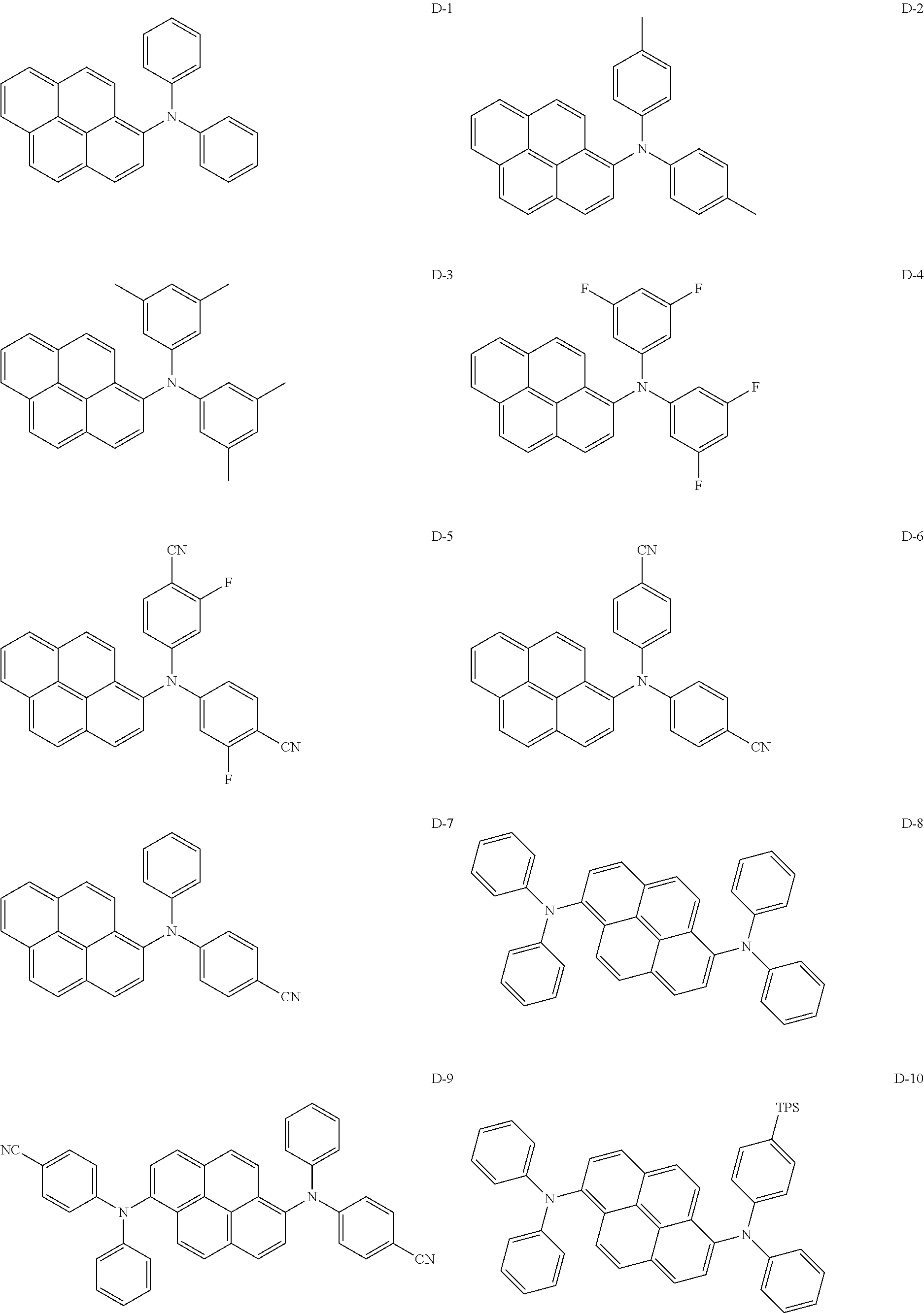

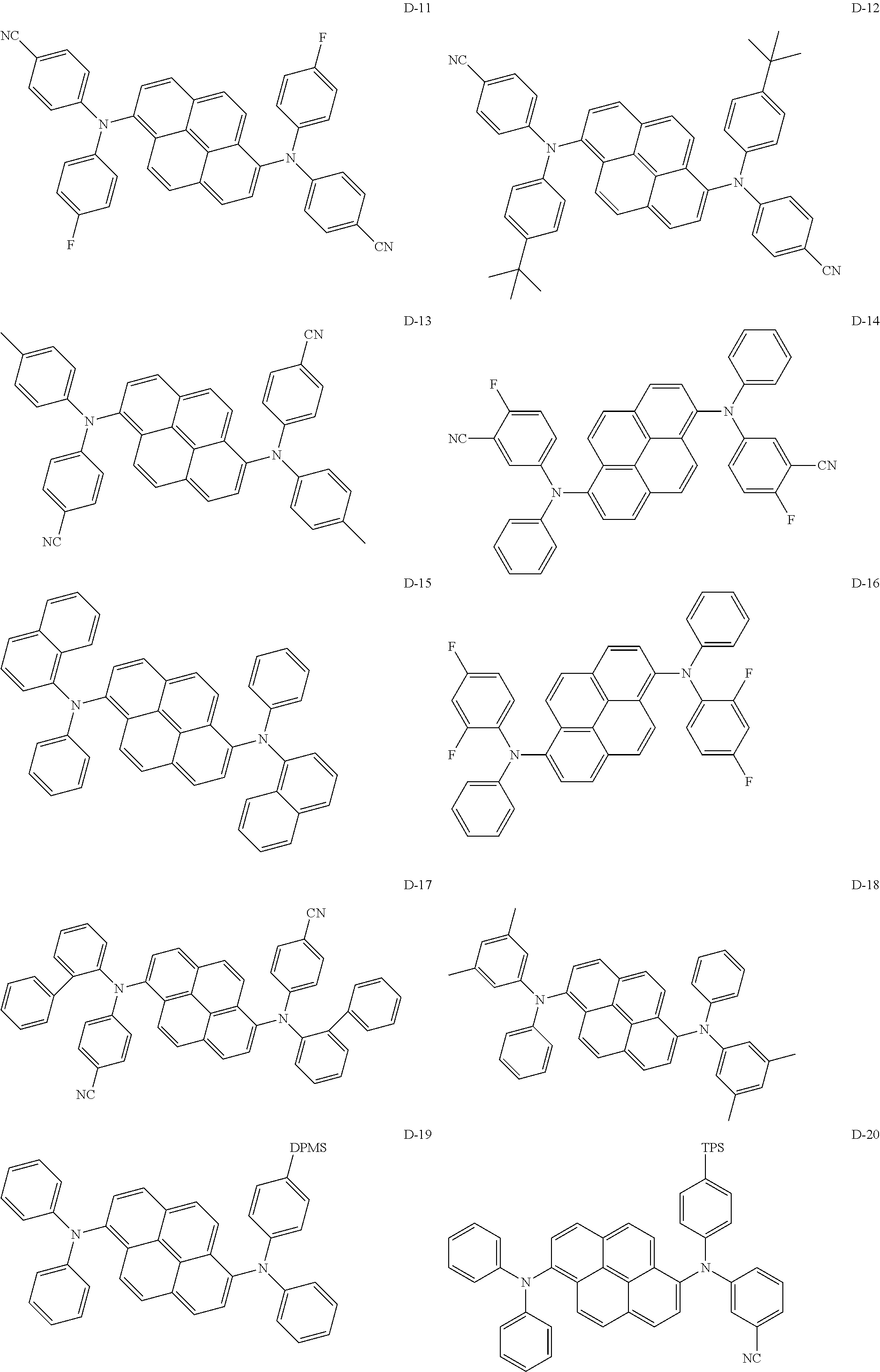

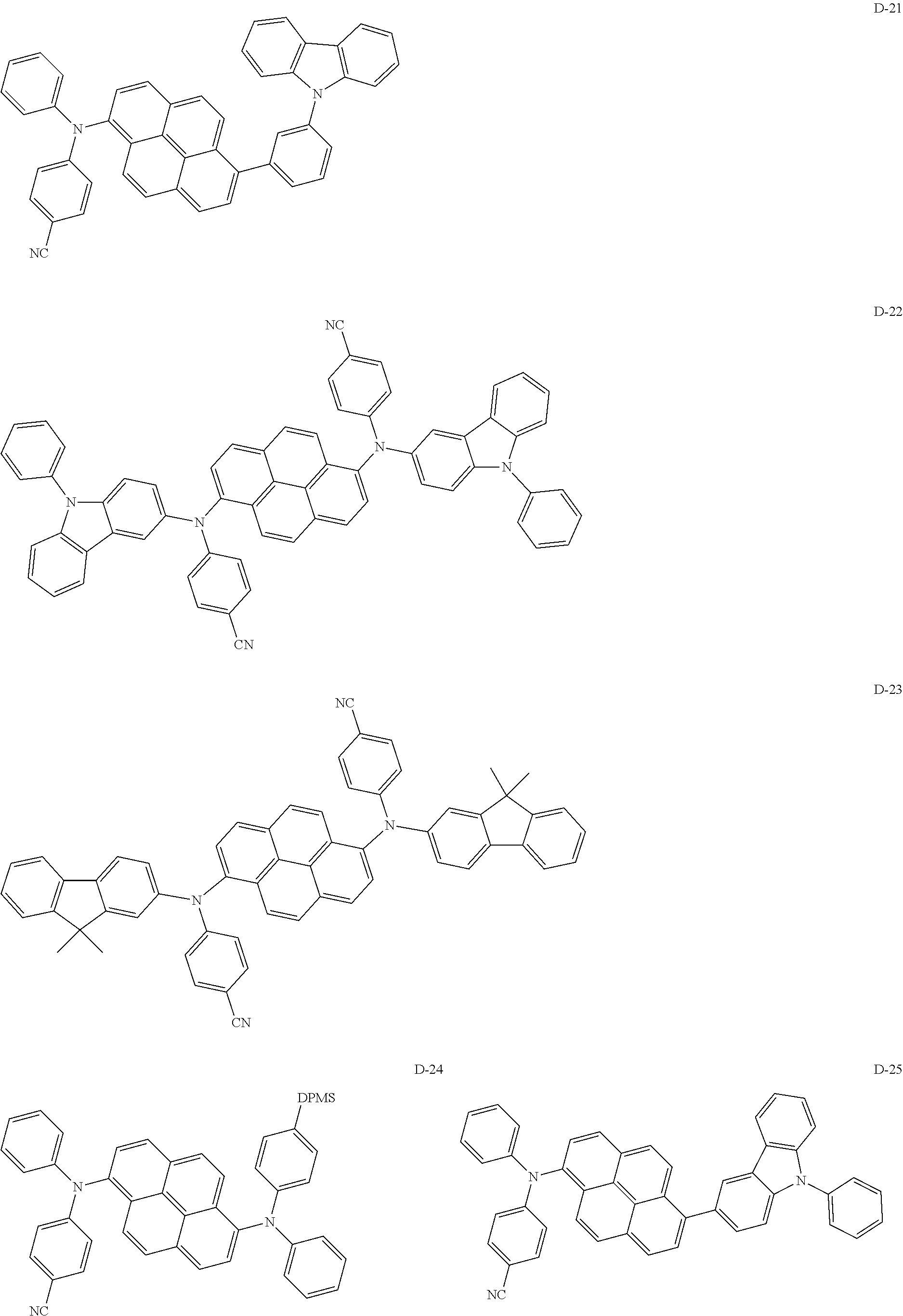

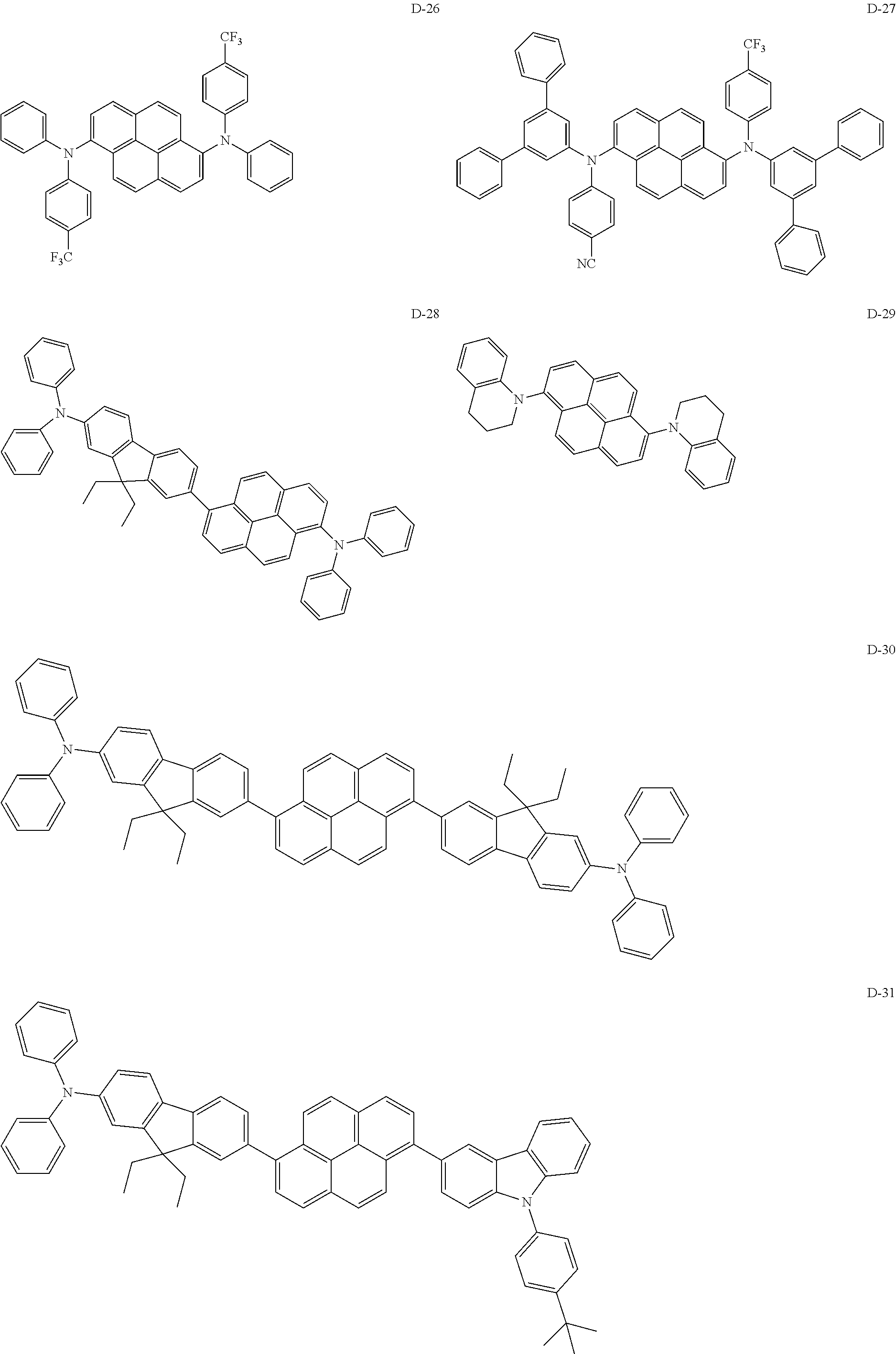

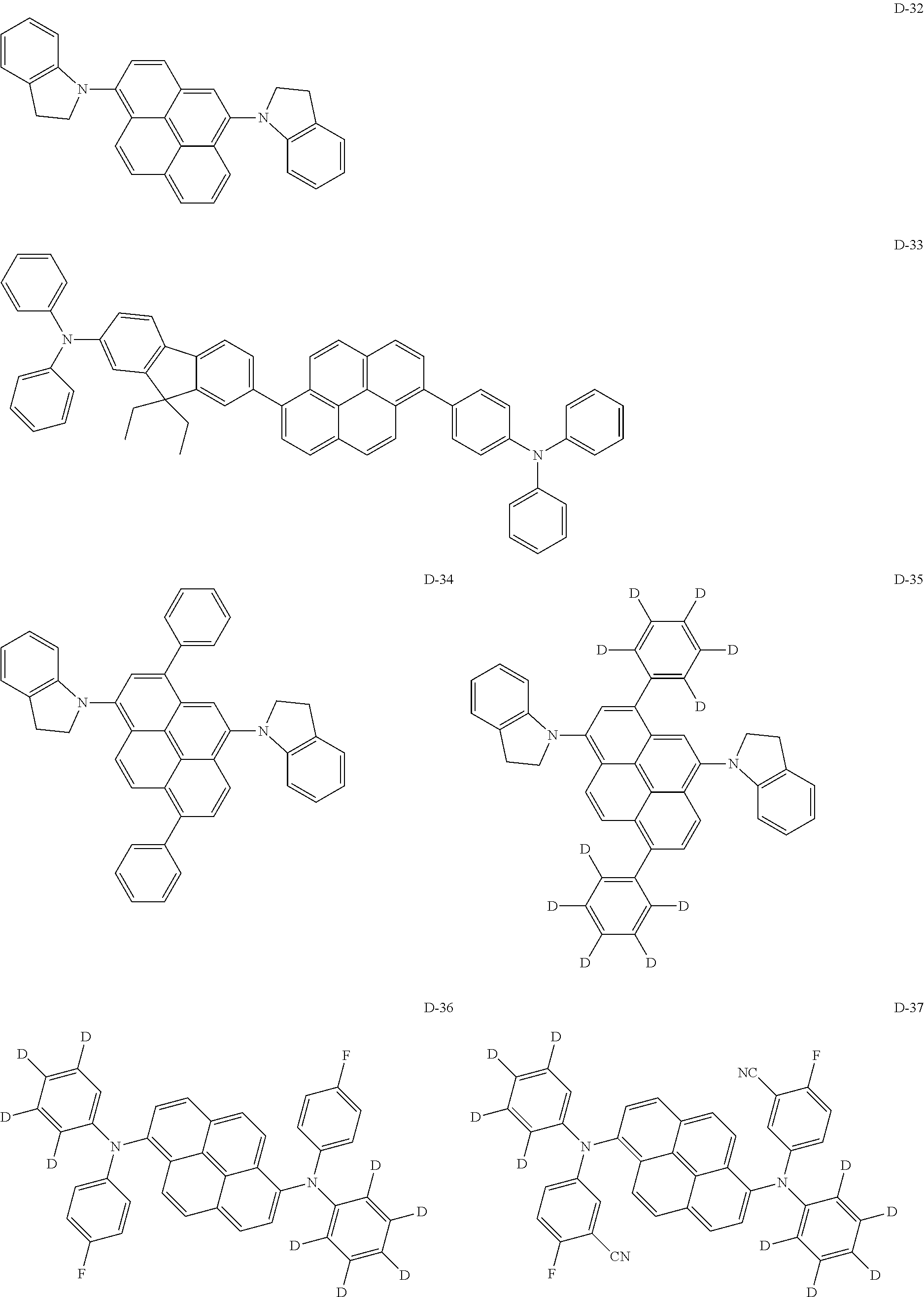

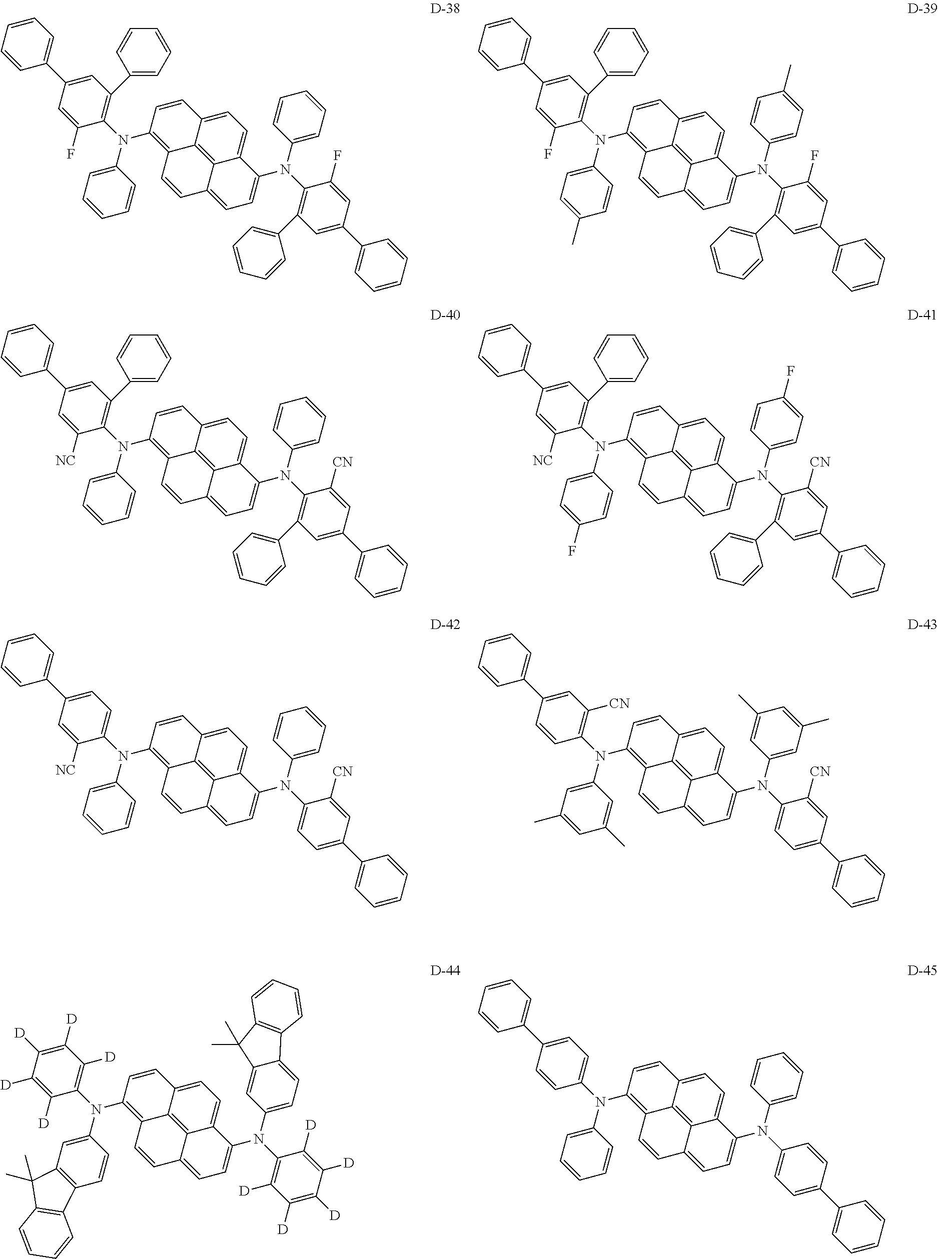

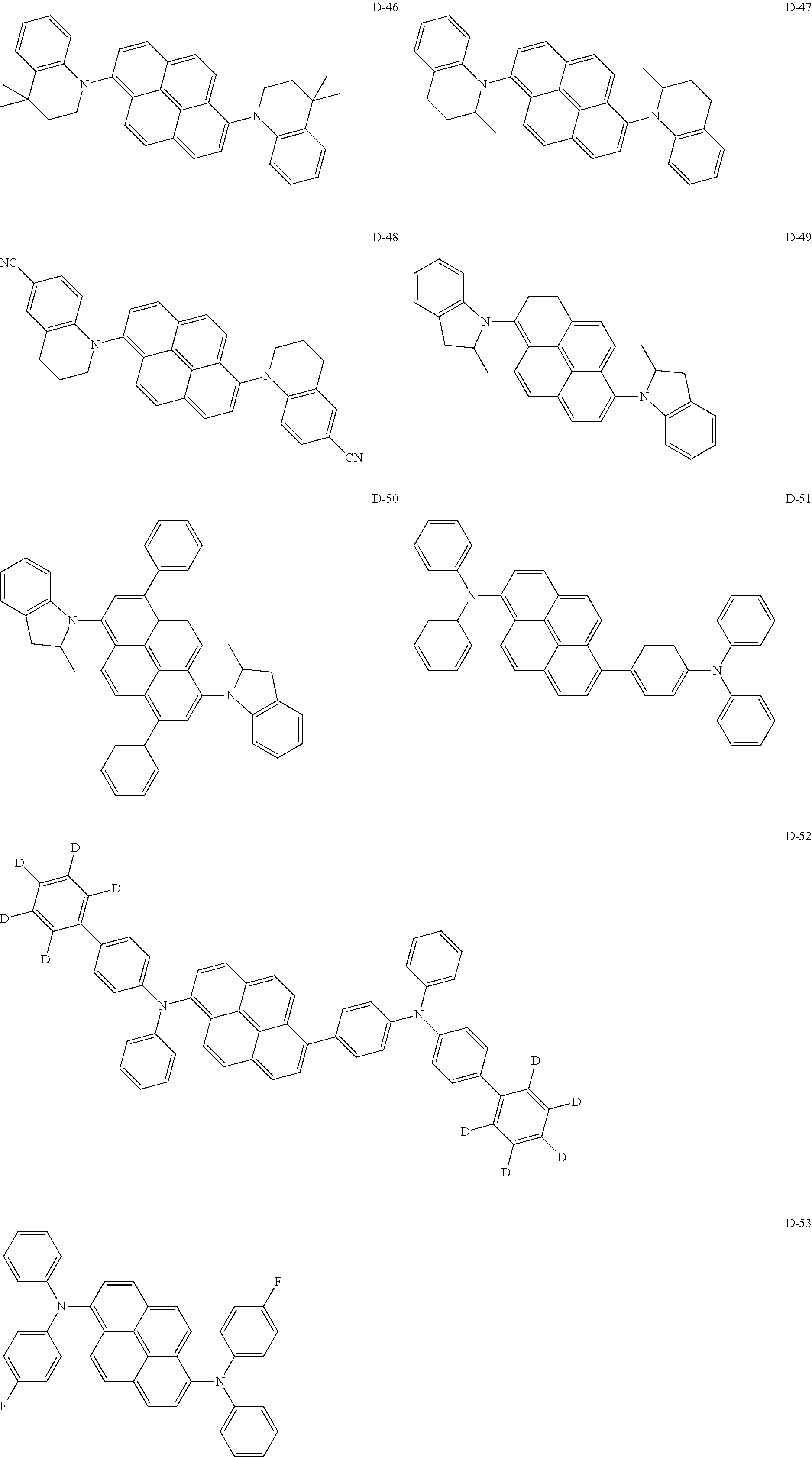

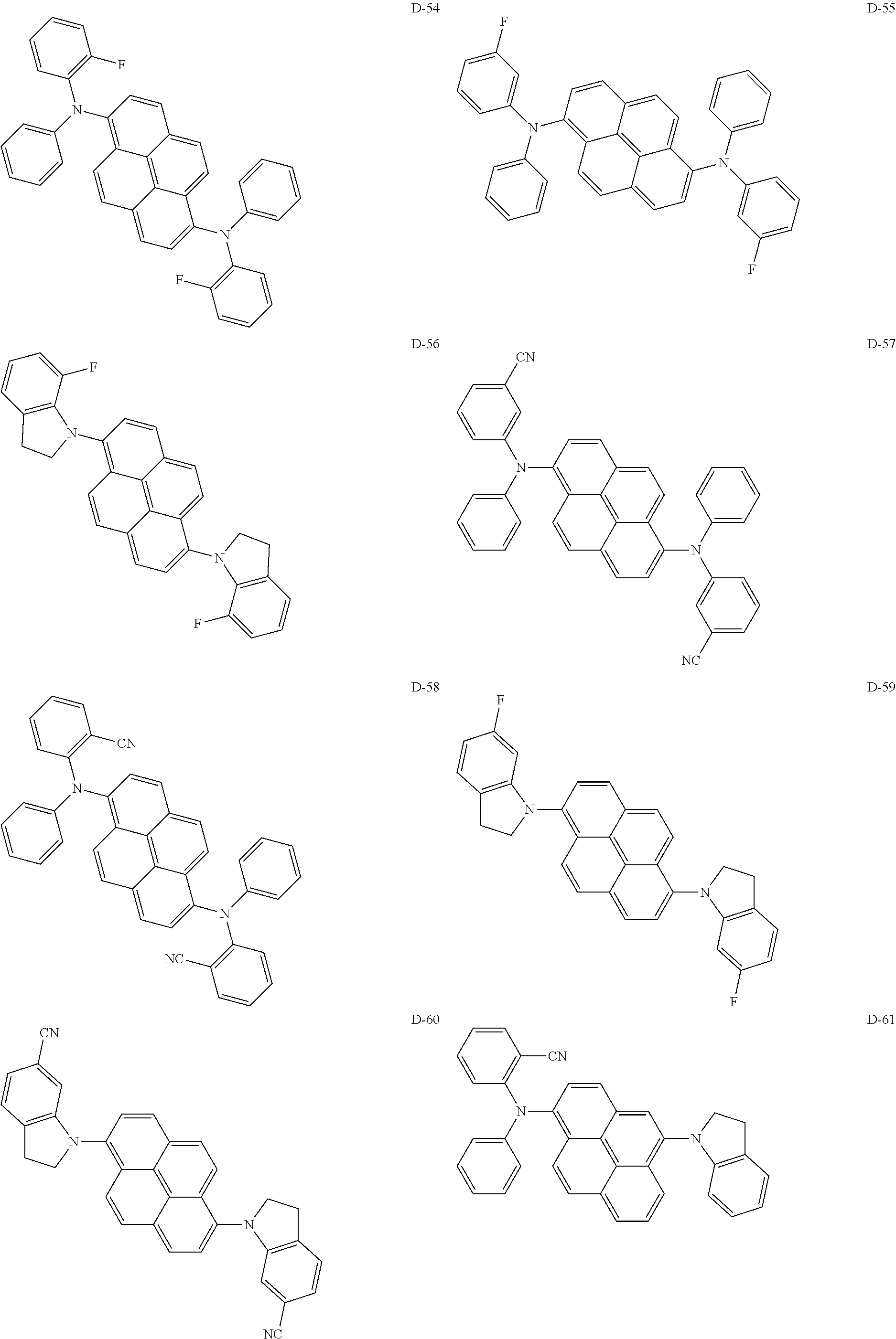

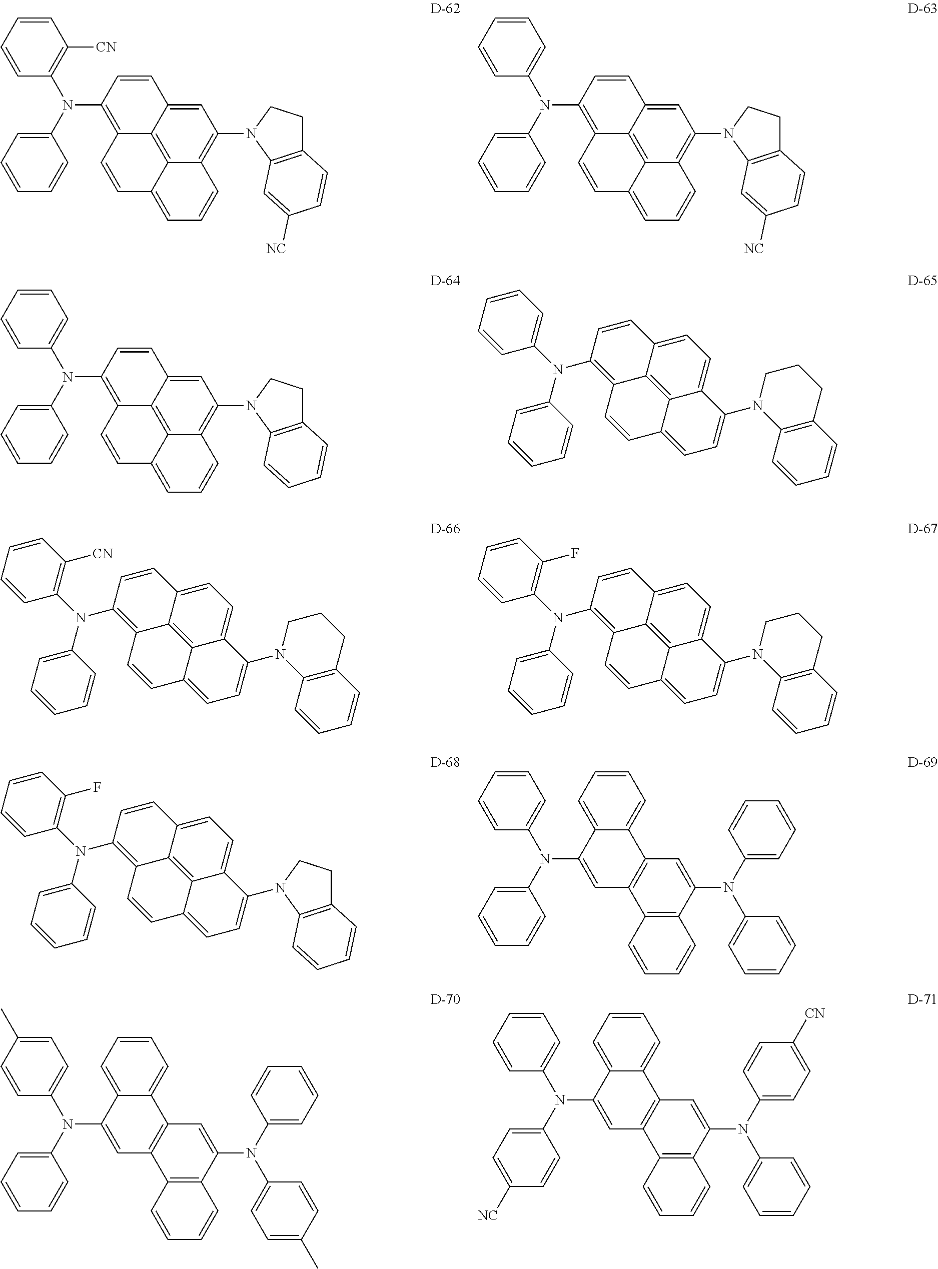

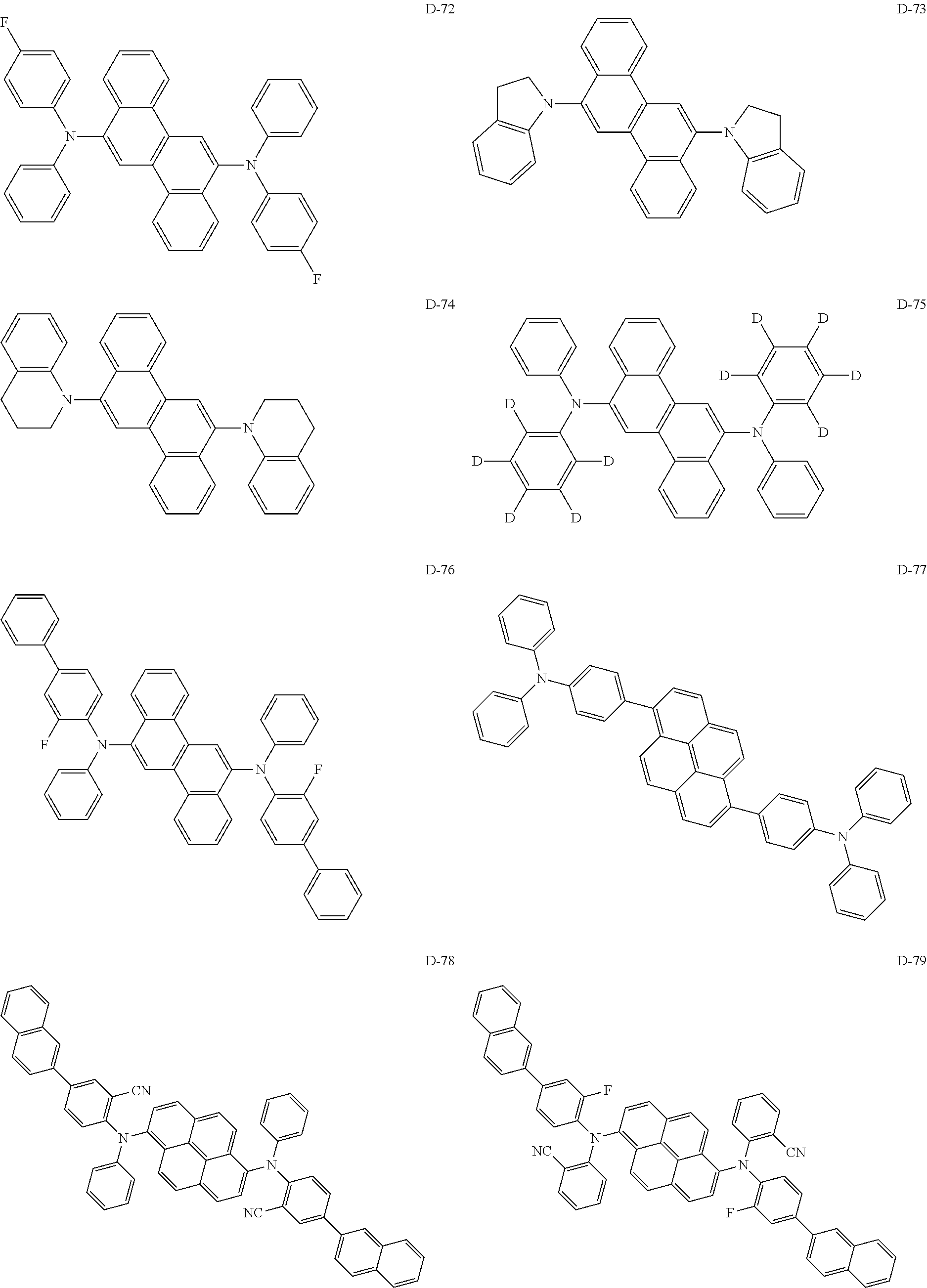

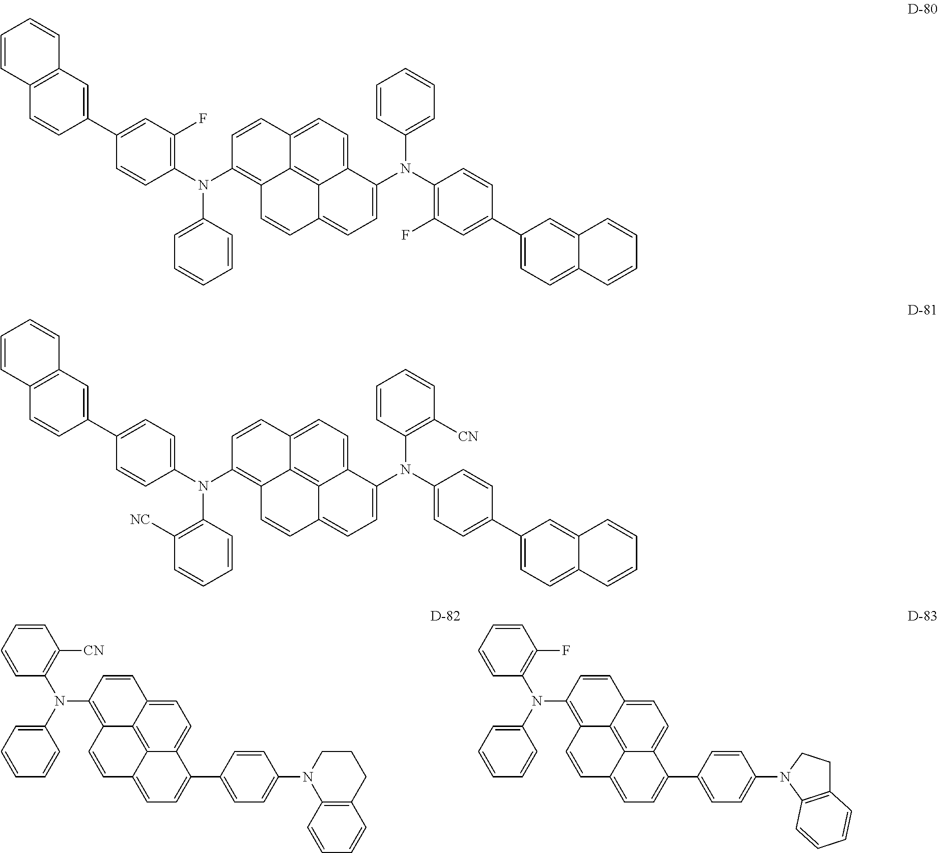 [SMILES: Fc1cc(-c2ccc3ccccc3c2)ccc1N(c1ccccc1)c1ccc2ccc3c(N(c4ccccc4)c4ccc(-c5ccc6ccccc6c5)cc4F)ccc4ccc1c2c43 ; N#Cc1ccccc1N(c1ccc(-c2ccc3ccccc3c2)cc1)c1ccc2ccc3c(N(c4ccc(-c5ccc6ccccc6c5)cc4)c4ccccc4C#N)ccc4ccc1c2c43 ; N#Cc1ccccc1N(c1ccccc1)c1ccc2ccc3c(-c4ccc(N5CCCc6ccccc65)cc4)ccc4ccc1c2c43 ; Fc1ccccc1N(c1ccccc1)c1ccc2ccc3c(-c4ccc(N5CCc6ccccc65)cc4)ccc4ccc1c2c43]

The light-emitting layer in the present invention, which emits a light, may be a mono-layer, or a multiple layer wherein two or more layers are laminated. When hosts and dopants are used in a mixture in the organic electroluminescent device of the present invention, the doping concentration of the dopant of formula 2 based on the host of formula 1 may be 1 to 10 wt %.

The host compounds and dopant compounds of the present invention have a high conductivity to holes and electrons, and have high stability to materials. Thus, they can improve luminescent efficiency and operating lifespan of the device.

The organic electroluminescent device according to the present invention comprises the host compounds of formula 1 and the dopant compounds of formula 2; and may further include at least one compound selected from the group consisting of arylamine-based compounds and styrylarylamine-based compounds. The specific arylamine-based compounds or styrylarylamine-based compounds are exemplified in paragraphs <212> to <224> of Korean Patent Application No. 10-2008-0060393 (Korean Patent Application Laying-Open No. 10-2010-0000772), but are not limited to them.

The organic electroluminescent device according to the present invention comprises the host compounds of formula 1 and the dopant compounds of formula 2 in an organic layer; and further comprises at least one metal selected from the group consisting of metals of Group 1, metals of Group 2, transition metals of the 4^{th} period, transition metals of the 5^{th} period, lanthanides and organic metals of d-transition elements of the Periodic Table, or at least one complex compound comprising said metal. The organic layer may comprise a light-emitting layer and a charge-generating layer.

In addition, the organic layer can form an organic electroluminescent device, which emits white light by further comprising a blue electroluminescent compound, a red electroluminescent compound or a green electroluminescent compound, in addition to the host compounds of formula 1 and the dopant compounds of formula 2. The blue, green or red electroluminescent compounds are disclosed in Korean Patent Application Nos. 10-2008-0123276 and 10-2008-0107606 (corresponding to Korean Patent Application Laying-Open Nos. 10-2010-0064712 and 10-2010-0048447, respectively) or Korean Patent Application Laying-Open No. 10-2010-0059653, but are not limited thereto.

In the organic electroluminescent device of the present invention, at least one layer (hereinafter, “a surface layer”) selected from a chalcogenide layer, a metal halide layer, and a metal oxide layer may be preferably placed on an inner surface(s) of one or both electrode(s). Specifically, a chalcogenide (including oxides) layer of silicon or aluminum is preferably placed on an anode surface of an electroluminescent medium layer, and a metal halide layer or metal oxide layer is preferably placed on a cathode surface of an electroluminescent medium layer. Said surface layer provides operational stability for the organic electroluminescent device. Preferably, said chalcogenide includes SiO_{X} (1≦X≦2), AlO_{X} (1≦X≦0.5), SiON, SiAlON, etc.; said metal halide includes LiF, MgF₂, CaF₂, a rare earth metal fluoride, etc.; and said metal oxide includes Cs₂O, Li₂O, MgO, SrO, BaO, CaO, etc.

Further, in the organic electroluminescent device according to the present invention, a mixed region of an electron transport compound and a reductive dopant, or a mixed region of a hole transport compound and an oxidative dopant may be placed on at least one surface of a pair of electrodes. By this way, the electron transport compound is reduced to an anion, and thus it becomes easier to inject and transport electrons from the mixed region to an electroluminescent medium. Further, the hole transport compound is oxidized to a cation, and thus it becomes easier to inject and transport holes from the mixed region to the electroluminescent medium. Preferably, the oxidative dopant includes various Lewis acids and acceptor compounds; and the reductive dopant includes alkali metals, alkali metal compounds, alkaline earth metals, rare-earth metals, and mixtures thereof. A reductive dopant layer may be employed as a charge-generating layer to prepare an electroluminescent device having two or more electroluminescent layers and emitting white light.

In order to form each layer constituting the organic electroluminescent device according to the present invention, dry film-forming methods, such as vacuum evaporation, sputtering, plasma, ion plating methods, etc., or wet film-forming methods, such as spin coating, dip coating, flow coating methods, etc., can be used.

When using a wet film-forming method, a thin film is formed by dissolving or dispersing the material constituting each layer in suitable solvents, such as ethanol, chloroform, tetrahydrofuran, dioxane, etc. The solvents are not specifically limited unless the material constituting each layer is soluble or dispersible and there is no problem in forming a layer.

Hereinafter, the preparation method of the host and dopant compounds of the present invention, and the luminescent properties of the device will be explained in detail with reference to the representative compounds of the present invention:

### Example 1

### Preparation of Compound C-1

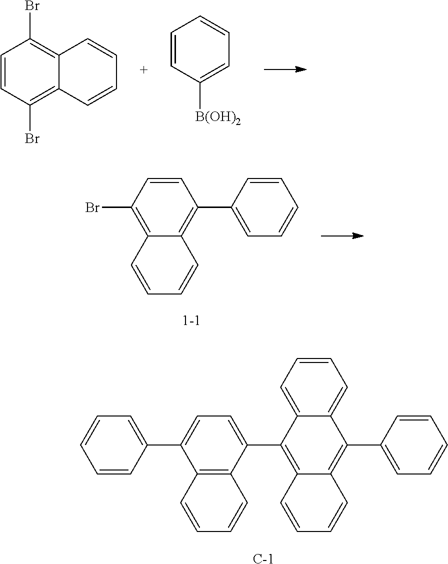

### Preparation of Compound 1-1

After adding 1,4-dibromonaphthalene (60.0 g, 0.20 mol), phenyl boronic acid (30.0 g, 0.24 mol), tetrakis(triphenylphosphine)palladium(0) [Pd(PPh₃)₄] (9.6 g, 8.3 mmol), and Na₂CO₃ (66.0 g, 0.60 mol) to a flask, 1200 mL of toluene, 300 mL of ethanol (EtOH), and 300 mL of H₂O were added to the reaction mixture and said ingredients were dissolved. The reaction mixture was stirred for 12 hours at 100° C. After the reaction, the reaction was completed by slowly adding H₂O and the organic layer was extracted with ethyl acetate (EA). The obtained organic layer was dried over MgSO₄ to remove residual moisture. The organic layer was separated through column to obtain compound 1-1 (26 g, Yield: 43%).

### Preparation of Compound C-1

After adding the obtain compound 1-1 (26.0 g, 0.09 mol), 10-phenylanthracen-9-yl boronic acid (30.0 g, 0.11 mol), Pd(PPh₃)₄ (6.3 g, 5.51 mmol), and K₂CO₃ (38.0 g, 0.30 mol) to a flask, 280 mL of toluene, 140 mL of EtOH, and 140 mL of H₂O were added to the reaction mixture and said ingredients were dissolved. The reaction mixture was stirred for 12 hours at 120° C. After the reaction, the reaction was completed by slowly adding H₂O and the organic layer was extracted with EA. The obtained organic layer was dried over MgSO₄ to remove residual moisture. The organic layer was separated through column to obtain compound C-1 (18 g, Yield: 42%).

### Example 2

### Preparation of Compound C-24

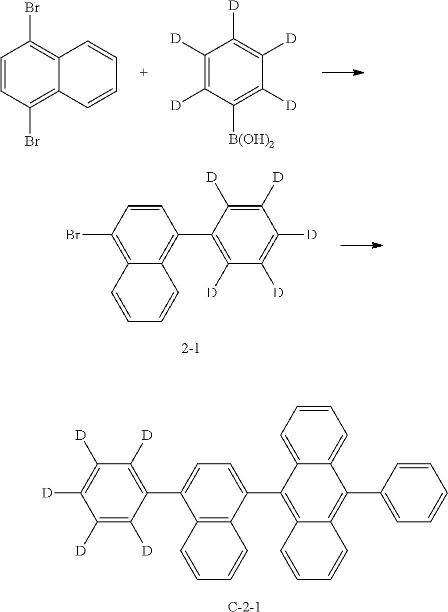

### Preparation of Compound 2-1

Compound 2-1 was prepared in the same synthesis method as in the preparation of compound 1-1 by using 1,4-dibromonaphthalene and d5-phenyl boronic acid.

### Preparation of Compound C-24

Compound C-24 was prepared (5 g, Yield: 52%) in the same synthesis method as in the preparation of compound C-1 by using compound 2-1 and 10-phenylanthracen-9-yl boronic acid.

### Example 3

### Preparation of Compound D-8

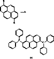

1,6-dibromopyrene (5.0 g, 13.8 mmol), diphenylamine (5.8 g, 34.2 mmol), palladium(II) acetate [Pd(OAc)₂](0.16 g, 0.71 mmol) and sodium t-butoxide (NaOtBu) (6.7 g, 69.7 mmol) were placed in a flask in the vacuum state under nitrogen atmosphere. Tri-t-butylphosphine [P(t-Bu)₃] (1 mL, 2.0 mmol) and toluene (80 mL) were added to the reaction mixture. The reaction mixture was stirred for 5 hours at 120° C. under reflux. After completing the reaction, the organic layer was extracted with EA and distilled water. The obtained organic layer was recrystallized using EA/methanol (MeOH) to obtain compound D-8 (2.5 g, 9.3 mmol, Yield: 30%).

### Example 4

### Preparation of Compound D-9

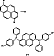

Compound D-9 was prepared (4 g, Yield: 50%) in the same synthesis method as in the preparation of compound D-8 by using 1,6-dibromopyrene and 4-(phenylamino)benzonitrile.

### Example 5

### Preparation of Compound D-10

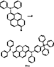

Compound D-10 was prepared (5.6 g, Yield: 40%) in the same synthesis method as in the preparation of compound D-8 by using 6-bromo-N,N-diphenylpyrene-1-amine and N-phenyl-4-(triphenylsilyl)aniline.

### Example 6

### Preparation of Compound D-21

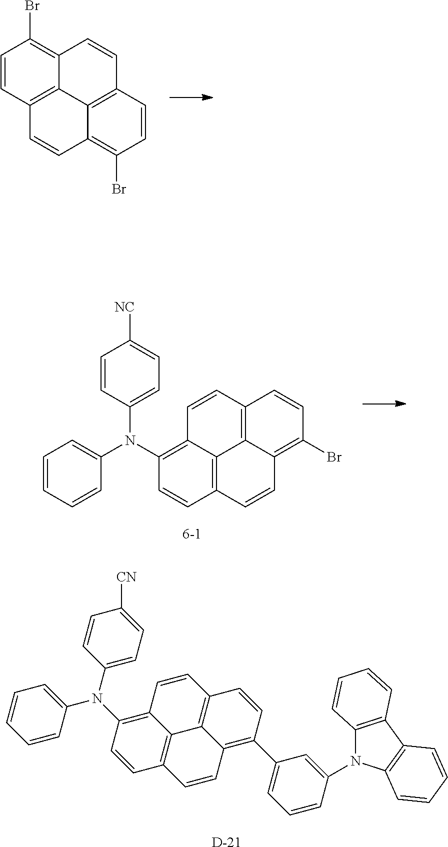

### Preparation of Compound 6-1

1,6-dibromopyrene (13.0 g, 0.068 mol), 4-(phenylamino)benzonitrile (52.0 g, 0.144 mol), Cu (7.6 g, 0.12 mol), Cs₂CO₃ (54.0 g, 0.167 mol) and 18-crown-6 (2.1 g, 0.008 mol) were added to a flask and were dissolved by adding 300 mL of 1,2-dichlorobenzene. The reaction mixture was stirred for 12 hours at 190° C. under reflux. After completing the reaction, 1,2-dichlorobenzene was removed by means of a distillation apparatus, and the organic layer was extracted with EA. The obtained organic layer was dried over MgSO₄ to remove residual moisture. The organic layer was separated through column to obtain compound 6-1 (15.5 g, Yield: 50%).

### Preparation of Compound D-21

After adding the obtain compound 6-1 (6.0 g, 0.012 mol), 3-(9H-carbazol-9-yl)phenyl boronic acid (5.4 g, 0.019 mol), Pd(PPh₃)₄ (732 mg, 0.63 mmol) and K₂CO₃ (5.2 g, 0.036 mol) to a flask, 40 mL of toluene, 20 mL of EtOH and 20 mL of H₂O were added to the reaction mixture and said ingredients were dissolved. The reaction mixture was stirred for 7 hours at 120° C. After the reaction, the reaction was completed by slowly adding H₂O and the organic layer was extracted with EA. The obtained organic layer was dried over MgSO₄ to remove residual moisture. The organic layer was separated through column to obtain compound D-21 (4 g, Yield: 50%).

### Example 7

### Preparation of Compound D-25

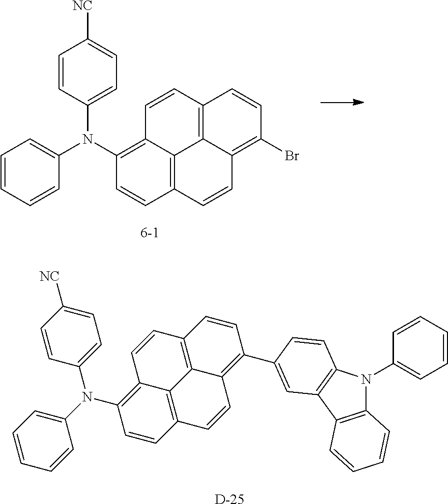

Compound D-25 was prepared (1.9 g, Yield: 30%) in the same synthesis method as in the preparation of compound D-21 by using compound 6-1 and 9-phenyl-9H-carbazol-3-yl boronic acid.

### Example 8

### Preparation of Compound D-32

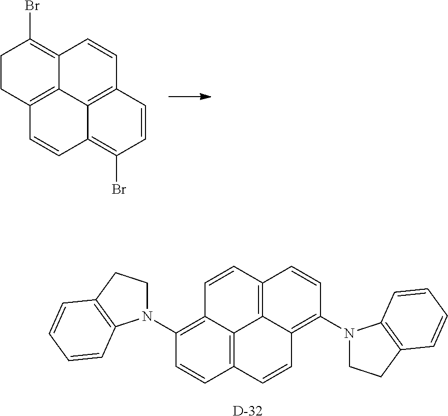

1,6-dibromopyrene (10.0 g, 27.8 mmol), indoline (6.9 mL, 61.1 mmol), palladium acetate (318 mg, 1.4 mmol), tri-t-butyl phosphine (0.7 mL, 2.8 mmol) and cesium carbonate (27 g, 83.3 mmol) were dissolved in toluene. The reaction mixture was stirred for 24 hours at 120° C. under reflux. After completing the reaction, the organic layer was extracted with EA and was rinsed with distilled water. The obtained organic layer was dried over MgSO₄ and was distilled under the reduced pressure. The organic layer was separated through column to obtain compound D-32 (5 g, Yield: 41%).

### Example 9

### Preparation of Compound D-69

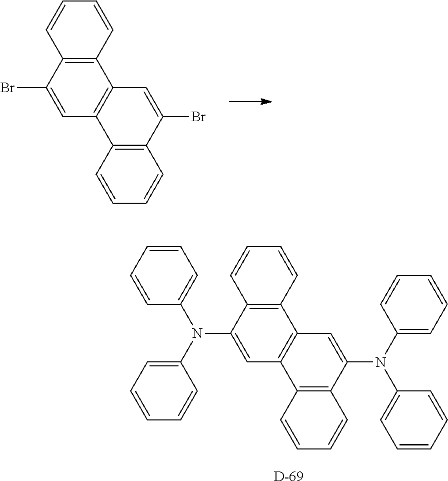

Compound D-69 was prepared (3.2 g, Yield: 36%) in the same synthesis method as in the preparation of compound D-8 by using 6,12-dibromochrycene and diphenylamine.

Host compound Nos. C-1 to C-51 and dopant compound Nos. D-1 to D-77 for an organic electroluminescent device were prepared in the same method as in Examples 1 to 9. Yield (%), MS/EIMS, UV (nm) and PL (nm) of the prepared compounds are provided in the table 1 below:

TABLE 1

| Compound | | MS/EIMS | | | |
|---|---|---|---|---|---|
| Nos. | Yiled(%) | Found | Calculated | UV(nm) | PL(nm) |
| C-1 | 42 | 456.6 | 457.3 | 395 | 438 |
| C-24 | 52 | 462.3 | 461.2 | | |
| D-8 | 30 | 536.2 | 536.6 | 248, 299, 422 | 469 |
| D-9 | 50 | 586.2 | 586.6 | 317, 416 | 446 |
| D-10 | 40 | 794.3 | 795.0 | 310, 426 | 456 |
| D-14 | 39 | 622.2 | 622.6 | | |
| D-16 | 45 | 608.2 | 608.6 | | |
| D-17 | 27 | 738.2 | 738.8 | 246, 314, 416 | 452 |
| D-19 | 34 | 732.3 | 732.9 | 340 | 461 |
| D-21 | 13.7 | 635.2 | 635.7 | | |
| D-22 | 30 | 916.3 | 917 | 246, 273, 317, | 565 |
| | | | | 419 | |
| D-23 | 60 | 818.3 | 819.0 | 243, 280, 332, | 476 |
| | | | | 419 | |
| D-25 | 30 | 635.2 | 635.7 | 250 | 448 |
| D-26 | 25 | 672.2 | 672.6 | 240, 260, 303, | 453 |
| | | | | 409 | |
| D-27 | 49.5 | 890.3 | 691.0 | 248, 324, 409 | 453 |
| D-28 | 28 | 756.3 | 756.9 | | |
| D-29 | 34 | 465.2 | 464.6 | 354 | 502 |
| D-30 | 51 | 976.4 | 977.2 | | |
| D-31 | 32 | 886.4 | 887.1 | | |
| D-32 | 41 | 437.2 | 436.5 | 354 | 502 |
| D-33 | 34 | 832.2 | 833.0 | | |
| D-69 | 36 | 562.7 | 563.4 | 269 | 446 |
| D-77 | 40 | 688.3 | 688.8 | | |

### Device Example 1

### Production of an OLED Device Using the Organic Electroluminescent Compound According to the Present Invention

An OLED device was produced using the light-emitting material according to the present invention. A transparent electrode indium tin oxide (ITO) thin film (15 Ω/sq) on a glass substrate for an organic light-emitting diode (OLED) device (Samsung Corning, Republic of Korea) was subjected to an ultrasonic washing with trichloroethylene, acetone, ethanol and distilled water, sequentially, and then was stored in isopropanol. Then, the ITO substrate was mounted on a substrate holder of a vacuum vapor depositing apparatus. 4,4′,4″-tris(N,N-(2-naphthyl)-phenylamino)triphenylamine was introduced into a cell of said vacuum vapor depositing apparatus, and then the pressure in the chamber of said apparatus was controlled to 10⁻⁶ torr. Thereafter, an electric current was applied to the cell to evaporate said introduced material, thereby forming a hole injection layer having a thickness of 60 nm on the ITO substrate. Then, N,N′-bis(α-naphthyl)-N,N′-diphenyl-4,4′-diamine was introduced into another cell of said vacuum vapor depositing apparatus, and was evaporated by applying electric current to the cell, thereby forming a hole transport layer having a thickness of 20 nm on the hole injection layer. The hole injection layer and the hole transport layer were formed, and then a light-emitting layer was vapor deposited thereon. Thereafter, compound C-1 was introduced into one cell of the vacuum vapor depositing apparatus, as a host material, and compound D-17 was introduced into another cell as a dopant. The two materials were evaporated at different rates and deposited in a doping amount of 3 wt % of the dopant based on the host, to form a light-emitting layer having a thickness of 30 nm on the hole transport layer. Then, tris(8-hydroxyquinoline)-aluminum (III) was deposited as an electron transport layer having a thickness of 30 nm onto the light-emitting layer. Then, after depositing lithium quinolate as an electron injection layer having a thickness of 2 nm on the electron transport layer, an Al cathode having a thickness of 150 nm was deposited by another vacuum vapor deposition apparatus on the electron injection layer. Thus, an OLED device was produced. All the materials used for producing the OLED device were purified by vacuum sublimation at 10⁻⁶ torr prior to use.

The produced OLED device showed a blue emission having a luminance of 720 cd/m² and a current density of 17.2 mA/cm².

### Device Example 2

### Production of an OLED Device Using the Organic Electroluminescent Compound According to the Present Invention

An OLED device was produced in the same manner as in Device Example 1, except for using compound C-45 as a host material and compound D-22 as a dopant.

The produced OLED device showed a blue emission having a luminance of 420 cd/m² and a current density of 11.3 mA/cm².

### Device Example 3

### Production of an OLED Device Using the Organic Electroluminescent Compound According to the Present Invention

An OLED device was produced in the same manner as in Device Example 1, except for using compound C-45 as a host material and compound D-23 as a dopant.

The produced OLED device showed a blue emission having a luminance of 1370 cd/m² and a current density of 25.7 mA/cm².

### Device Example 4

### Production of an OLED Device Using the Organic Electroluminescent Compound According to the Present Invention

An OLED device was produced in the same manner as in Device Example 1, except for using compound C-1 as a host material and compound D-26 as a dopant.

The produced OLED device showed a blue emission having a luminance of 1340 cd/m² and a current density of 35.9 mA/cm².

### Device Example 5

### Production of an OLED Device Using the Organic Electroluminescent Compound According to the Present Invention

An OLED device was produced in the same manner as in Device Example 1, except for using compound C-45 as a host material and compound D-27 as a dopant.

The produced OLED device showed a blue emission having a luminance of 620 cd/m² and a current density of 17.8 mA/cm².

### Device Example 6

### Production of an OLED Device Using the Organic Electroluminescent Compound According to the Present Invention

An OLED device was produced in the same manner as in Device Example 1, except for using compound C-1 as a host material and compound D-29 as a dopant.

The produced OLED device showed a blue emission having a luminance of 1300 cd/m² and a current density of 21.1 mA/cm².

### Device Example 7

### Production of an OLED Device Using the Organic Electroluminescent Compound According to the Present Invention

An OLED device was produced in the same manner as in Device Example 1, except for using compound C-45 as a host material and compound D-32 as a dopant.

The produced OLED device showed a blue emission having a luminance of 2900 cd/m² and a current density of 38.8 mA/cm².

### Comparative Example 1

### Production of an OLED Device Using Conventional Light-Emitting Material

After a hole injection layer and a hole transport layer were produced in the same manner as in Device Example 1, dinaphthylanthracene (DNA) was introduced into one cell of the vacuum vapor depositing apparatus as a host material, and compound D-17 was introduced into another cell as a dopant. By using 100:1 of the deposition rate, a light-emitting layer having a thickness of 30 nm was deposited on the hole transport layer. Then, as in the same method as in Device Example 1, an electron transport layer and an electron injection layer were deposited on the light-emitting layer. An Al cathode having a thickness of 150 nm was deposited by another vacuum vapor deposition apparatus on the electron injection layer. Thus, an OLED device was produced.

The produced OLED device showed a blue emission having a luminance of 1330 cd/m² and a current density of 54.2 mA/cm².

The combination of dopant compounds and host compounds of the present invention possesses superior luminescent efficacy over conventional materials. The organic electroluminescent device comprising the combination of dopant compounds and host compounds of the present invention shows a blue emission and has high current efficiency.

1. An organic electroluminescent device, comprising at least one host compound represented by the following formula 1 and at least one dopant compound represented by the following formula 2: 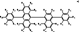
wherein
R₁ to R₂₄ each independently represent hydrogen, deuterium, a halogen, a substituted or unsubstituted (C1-C30)alkyl group, a substituted or unsubstituted (C1-C30)alkoxy group, a substituted or unsubstituted (C6-C30)aryl group, a substituted or unsubstituted 3- to 30-membered heteroaryl group, —SiR₃₁R₃₂R₃₃, a cyano group or a hydroxyl group, or R₂₀ to R₂₄ are linked each other to form a substituted or unsubstituted mono- or polycyclic, 3- to 30-membered alicyclic or aromatic ring whose carbon atom(s) may be replaced with at least one hetero atom selected from nitrogen, oxygen and sulfur;
R₃₁ to R₃₃ each independently represent hydrogen, deuterium, a halogen, a substituted or unsubstituted (C1-C30)alkyl group, a substituted or unsubstituted (C6-C30)aryl group, or a substituted or unsubstituted 3- to 30-membered heteroaryl group; and
the heteroaryl group contains at least one hetero atom selected from the group consisting of B, N, O, S, P(═O), Si and P, 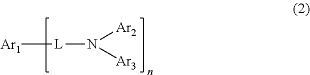
wherein
Ar₁ represents a substituted or unsubstituted pyrene ring, or a substituted or unsubstituted chrycene ring;
L represents a single bond, a substituted or unsubstituted (C6-C30)aryl group, or a substituted or unsubstituted 3- to 30-membered heteroaryl group;
Ar₂ and Ar₃ each independently represent hydrogen, deuterium, a halogen, a substituted or unsubstituted (C1-C30)alkyl group, a substituted or unsubstituted (C6-C30)aryl group, or a substituted or unsubstituted 3- to 30-membered heteroaryl group; or are linked with an adjacent substituent(s) to form a substituted or unsubstituted mono- or polycyclic, 3- to 30-membered alicyclic or aromatic ring whose carbon atom(s) may be replaced with at least one hetero atom selected from nitrogen, oxygen and sulfur;
n represents an integer of 1 to 2; where n is an integer of 2, the structural units within the square brackets are the same or different; and
the heteroaryl group contains at least one hetero atom selected from the group consisting of B, N, O, S, P(═O), Si and P.

2. The organic electroluminescent device according to claim 1, wherein in formula 1, R₁ to R₂₄ each independently represent hydrogen, deuterium, fluorine, a substituted or unsubstituted (C1-C10)alkyl group, a substituted or unsubstituted (C1-C10)alkoxy group, a substituted or unsubstituted (C6-C15)aryl group, or a substituted or unsubstituted 3- to 15-membered heteroaryl group, —SiR₃₁R₃₂R₃₃, a cyano group or a hydroxyl group; or R₂₀ to R₂₄ are linked together to form a substituted or unsubstituted mono- or polycyclic, 3- to 30-membered alicyclic or aromatic ring whose carbon atom(s) may be replaced with at least one hetero atom selected from nitrogen, oxygen and sulfur; and R₃₁ to R₃₃ each independently represent an unsubstituted (C1-C10)alkyl group or an unsubstituted (C6-C15)aryl group; and in formula 2, L represents a single bond or an unsubstituted (C6-C15)aryl group; and Ar₂ and Ar₃ each independently represent a substituted or unsubstituted (C6-C15)aryl group, or are linked with an adjacent substituent(s) to form a substituted or unsubstituted mono- or polycyclic, 3- to 15-membered alicyclic or aromatic ring whose carbon atom(s) may be replaced with at least one hetero atom selected from nitrogen, oxygen and sulfur.

3. The organic electroluminescent device according to claim 1, wherein the substituents of the substituted (C1-C30)alkyl group, the substituted (C1-C30)alkoxy group, the substituted (C6-C30)aryl group, the substituted 3- to 30-membered heteroaryl group, and the substituted mono- or polycyclic, 3- to 30-membered alicyclic or aromatic ring in R₁ to R₂₄, R₃₁ to R₃₃, L, and Ar₁ to Ar₃ groups of formulae 1 and 2 are independently at least one selected from the group consisting of deuterium; a halogen; a (C1-C30)alkyl group; a halo(C1-C30)alkyl group; a (C1-C30)alkoxy group; a (C6-C30)aryloxy group; a (C6-C30)aryl group; a 3- to 30-membered heteroaryl group; a 3- to 30-membered heteroaryl group substituted with a (C6-C30)aryl group; a (C6-C30)aryl group substituted with a 3- to 30-membered heteroaryl group; a (C3-C30)cycloalkyl group; a 5- to 7-membered heterocycloalkyl group; a tri(C1-C30)alkylsilyl group; a tri(C6-C30)arylsilyl group; a di(C1-C30)alkyl(C6-C30)arylsilyl group; a (C1-C30)alkyldi(C6-C30)arylsilyl group; a (C2-C30)alkenyl group; a (C2-C30)alkynyl group; a cyano group; a (C1-C30)alkylthio group; a (C6-C30)arylthio group; an N-carbazolyl group; a mono- or di(C1-C30)alkylamino group; a mono- or di(C6-C30)arylamino group; a (C1-C30)alkyl(C6-C30)arylamino group; a di(C6-C30)arylboronyl group; a di(C1-C30)alkylboronyl group; a (C1-C30)alkyl(C6-C30)arylboronyl group; a (C6-C30)aryl(C1-C30)alkyl group; a (C1-C30)alkyl(C6-C30)aryl group; a carboxyl group; a nitro group; and a hydroxyl group.

4. The organic electroluminescent device according to claim 1, wherein Ar₁ is selected from the group consisting of the following structures: 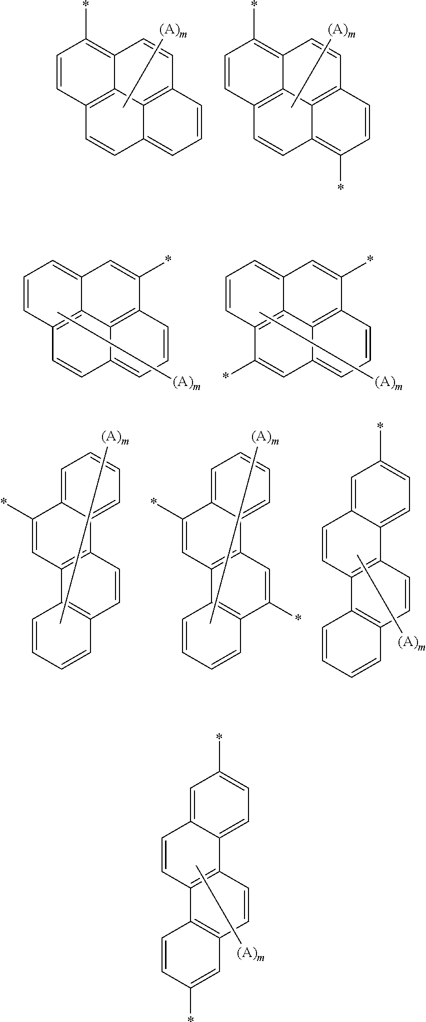
wherein
A represents deuterium, a halogen, a (C1-C30)alkyl group, a halo(C1-C30)alkyl group, a (C6-C30)aryl group, a 3- to 30-membered heteroaryl group, a 3- to 30-membered heteroaryl group substituted with a (C6-C30)aryl group, a (C6-C30)aryl group substituted with a 3- to 30-membered heteroaryl group; a (C3-C30)cycloalkyl group; a 5- to 7-membered heterocycloalkyl group; a tri(C1-C30)alkylsilyl group; a tri(C6-C30)arylsilyl group; a di(C1-C30)alkyl(C6-C30)arylsilyl group; a (C1-C30)alkyldi(C6-C30)arylsilyl group; a (C2-C30)alkenyl group; a (C2-C30)alkynyl group; a cyano group; an N-carbazolyl group; a di(C1-C30)alkylamino group; a di(C6-C30)arylamino group; a (C1-C30)alkyl(C6-C30)arylamino group; a di(C6-C30)arylboronyl group; a di(C1-C30)alkylboronyl group; a (C1-C30)alkyl(C6-C30)arylboronyl group; a (C6-C30)aryl(C1-C30)alkyl group; a (C1-C30)alkyl(C6-C30)aryl group; a carboxyl group; a nitro group; and a hydroxyl group; and
m represents an integer of 0 to 4.

5. The organic electroluminescent device according to claim 1, wherein the host compound is selected from the group consisting of:

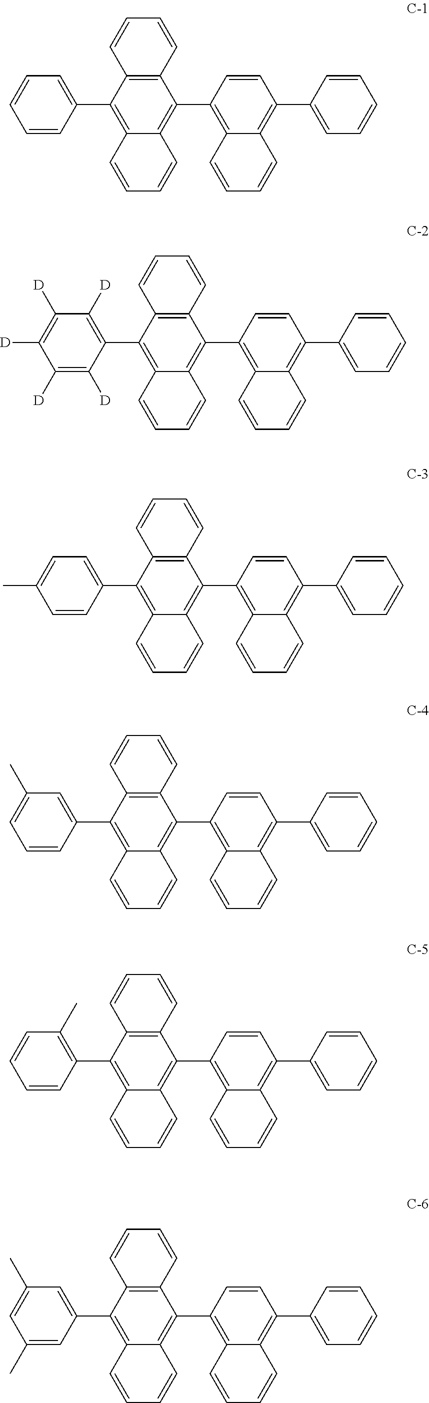

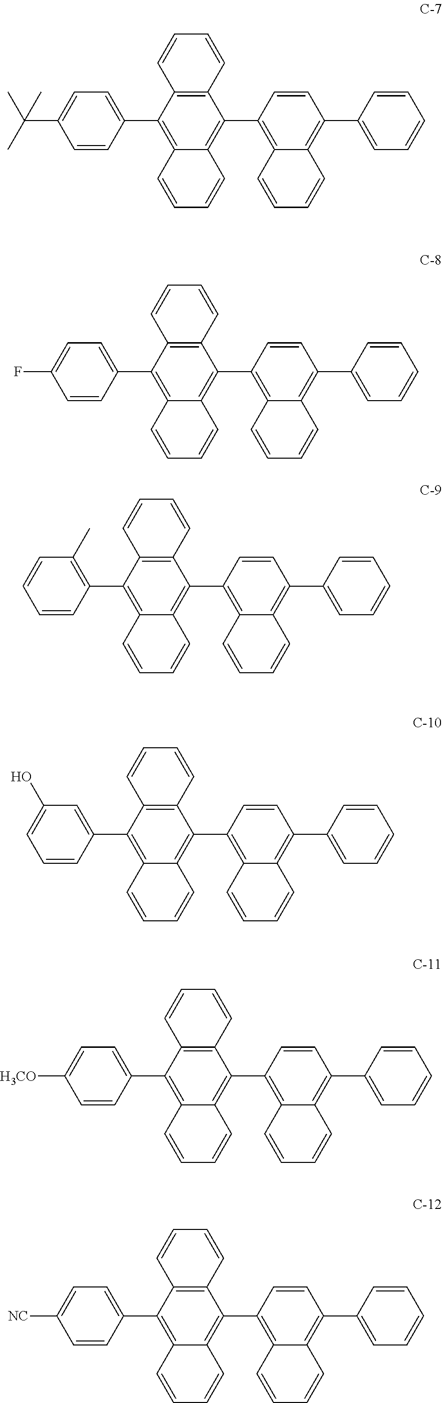

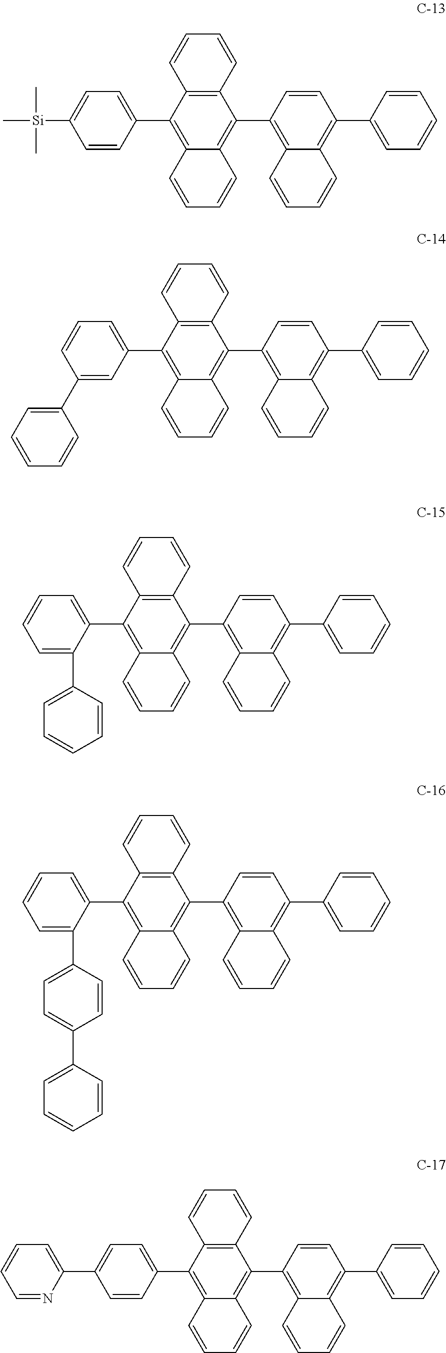

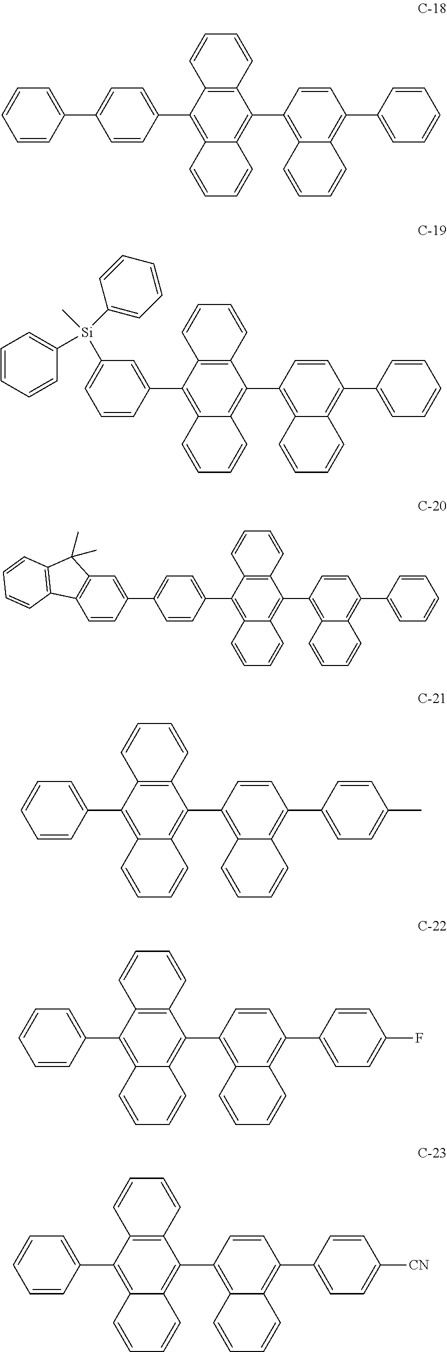

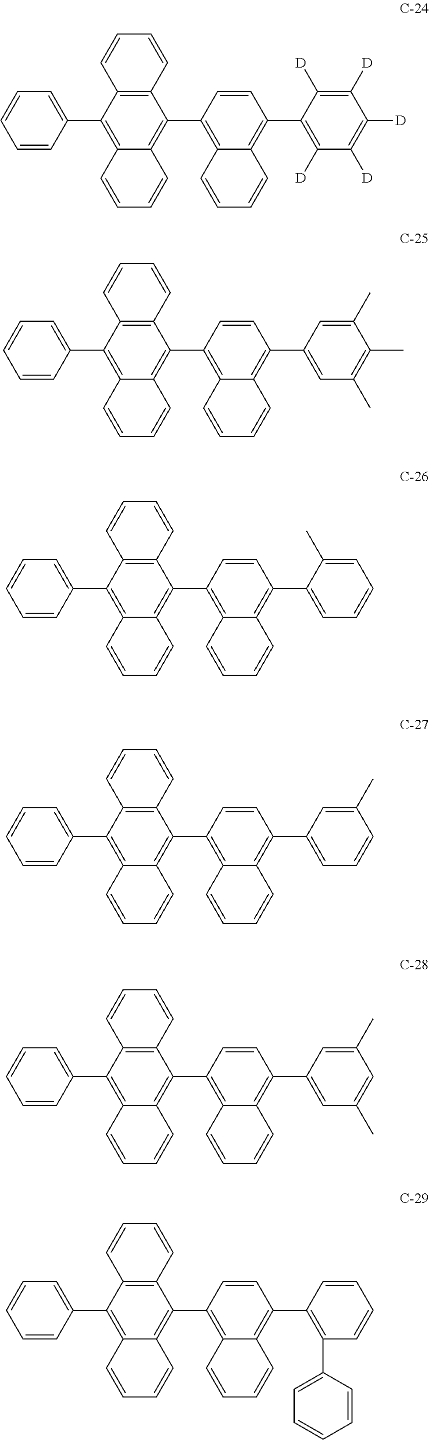

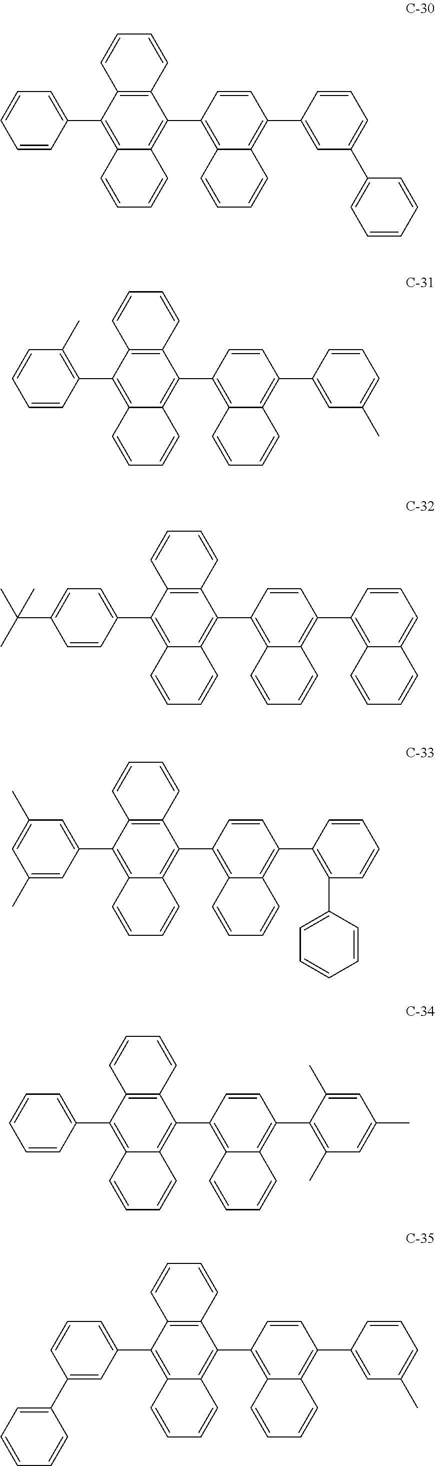

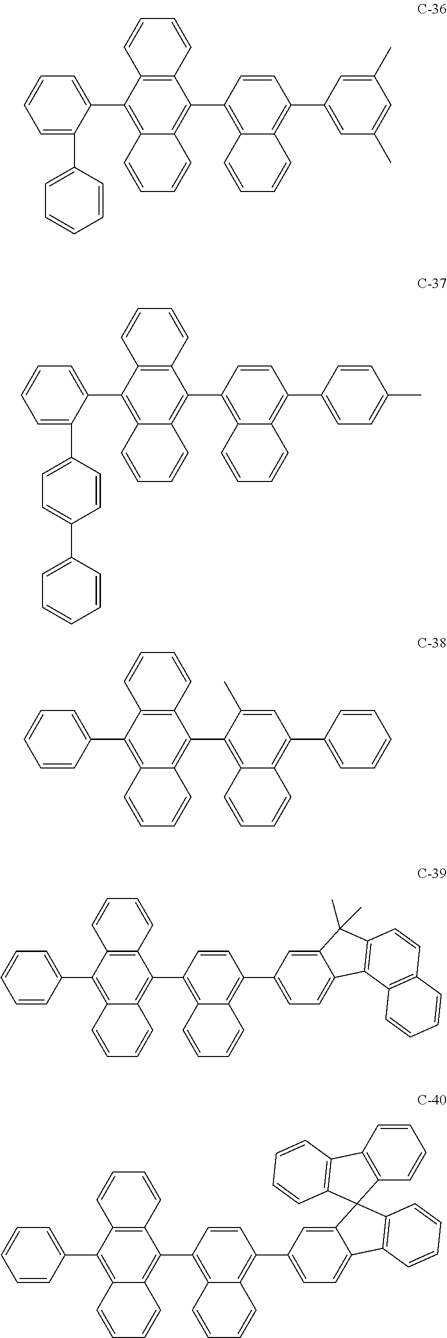

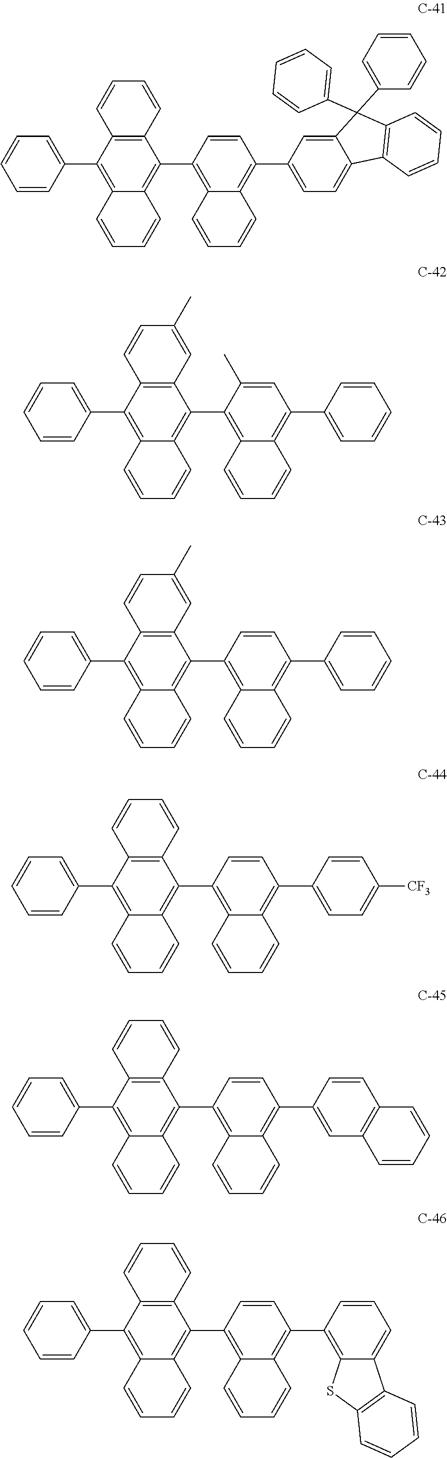

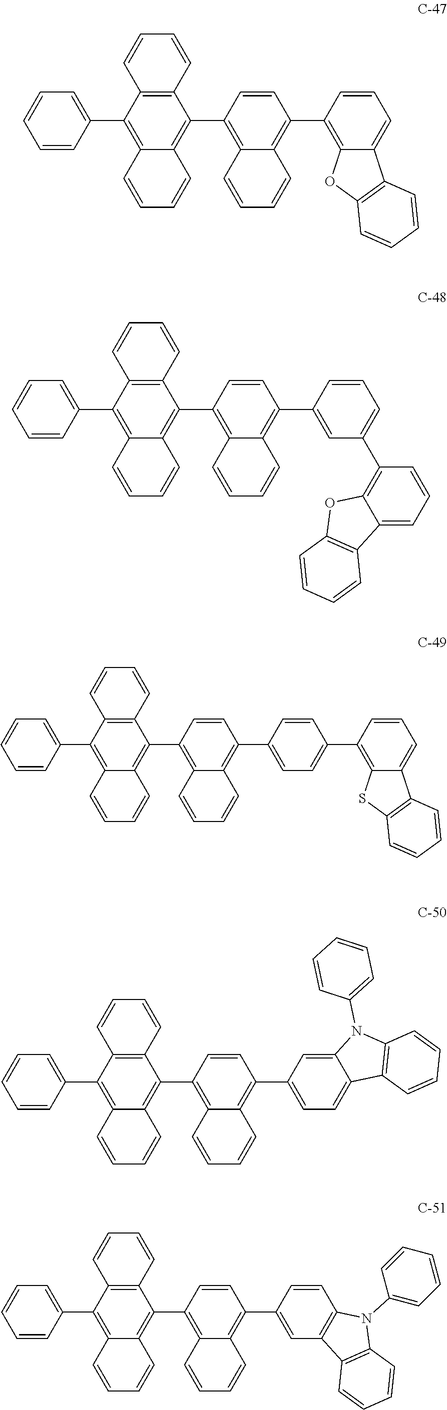 [SMILES: c1ccc(-c2c3ccccc3c(-c3ccc(-c4cccc5c4oc4ccccc45)c4ccccc34)c3ccccc23)cc1 ; c1ccc(-c2c3ccccc3c(-c3ccc(-c4cccc(-c5cccc6c5oc5ccccc56)c4)c4ccccc34)c3ccccc23)cc1 ; c1ccc(-c2c3ccccc3c(-c3ccc(-c4ccc(-c5cccc6c5sc5ccccc56)cc4)c4ccccc34)c3ccccc23)cc1 ; c1ccc(-c2c3ccccc3c(-c3ccc(-c4ccc5c6ccccc6n(-c6ccccc6)c5c4)c4ccccc34)c3ccccc23)cc1 ; c1ccc(-c2c3ccccc3c(-c3ccc(-c4ccc5c(c4)c4ccccc4n5-c4ccccc4)c4ccccc34)c3ccccc23)cc1]

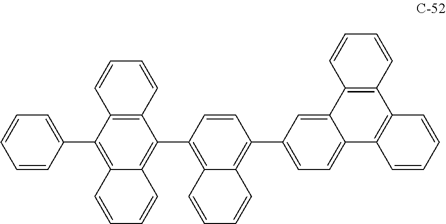 [SMILES: c1ccc(-c2c3ccccc3c(-c3ccc(-c4ccc5c6ccccc6c6ccccc6c5c4)c4ccccc34)c3ccccc23)cc1]

6. The organic electroluminescent device according to claim 1, wherein the dopant compound is selected from the group consisting of: 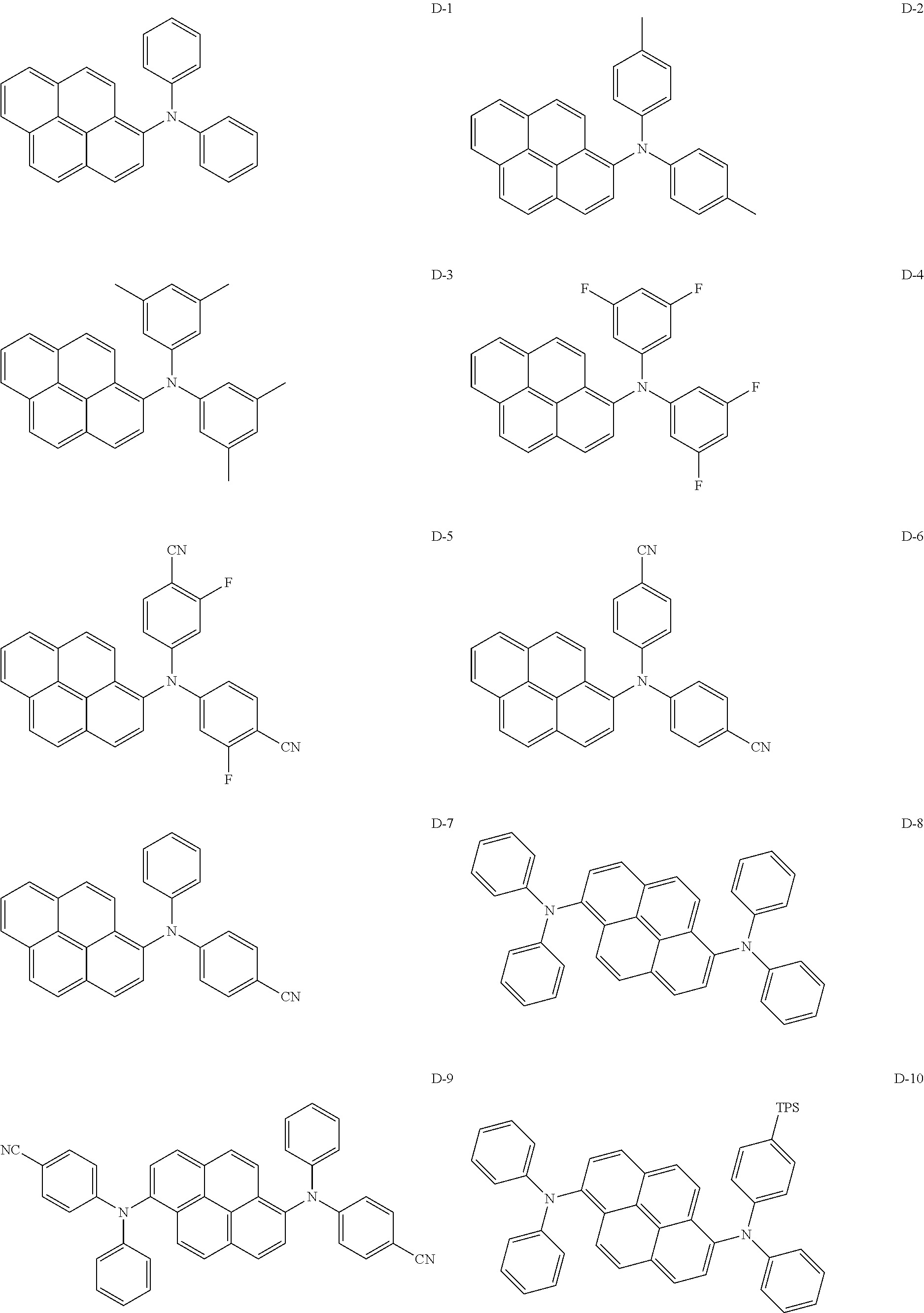 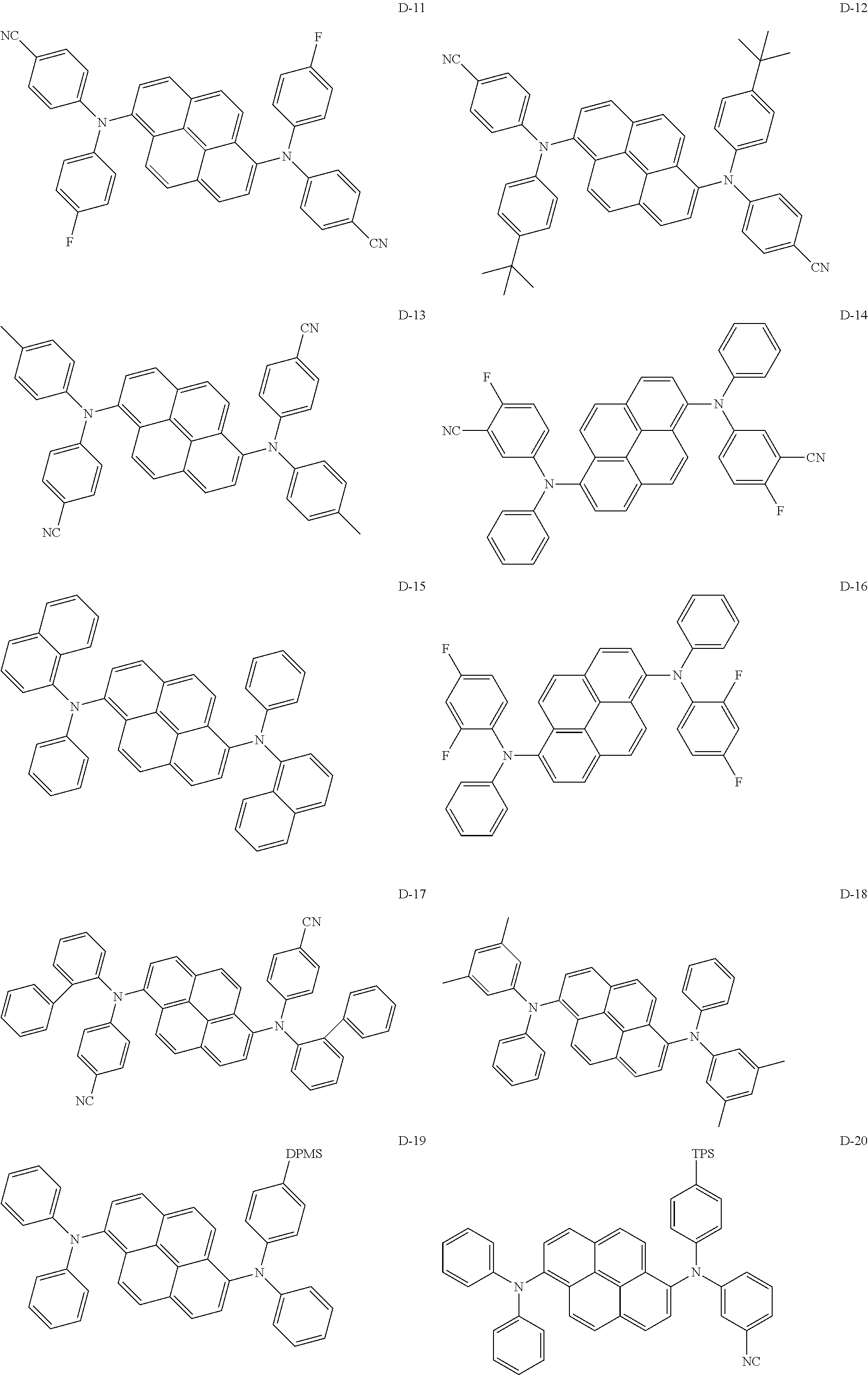 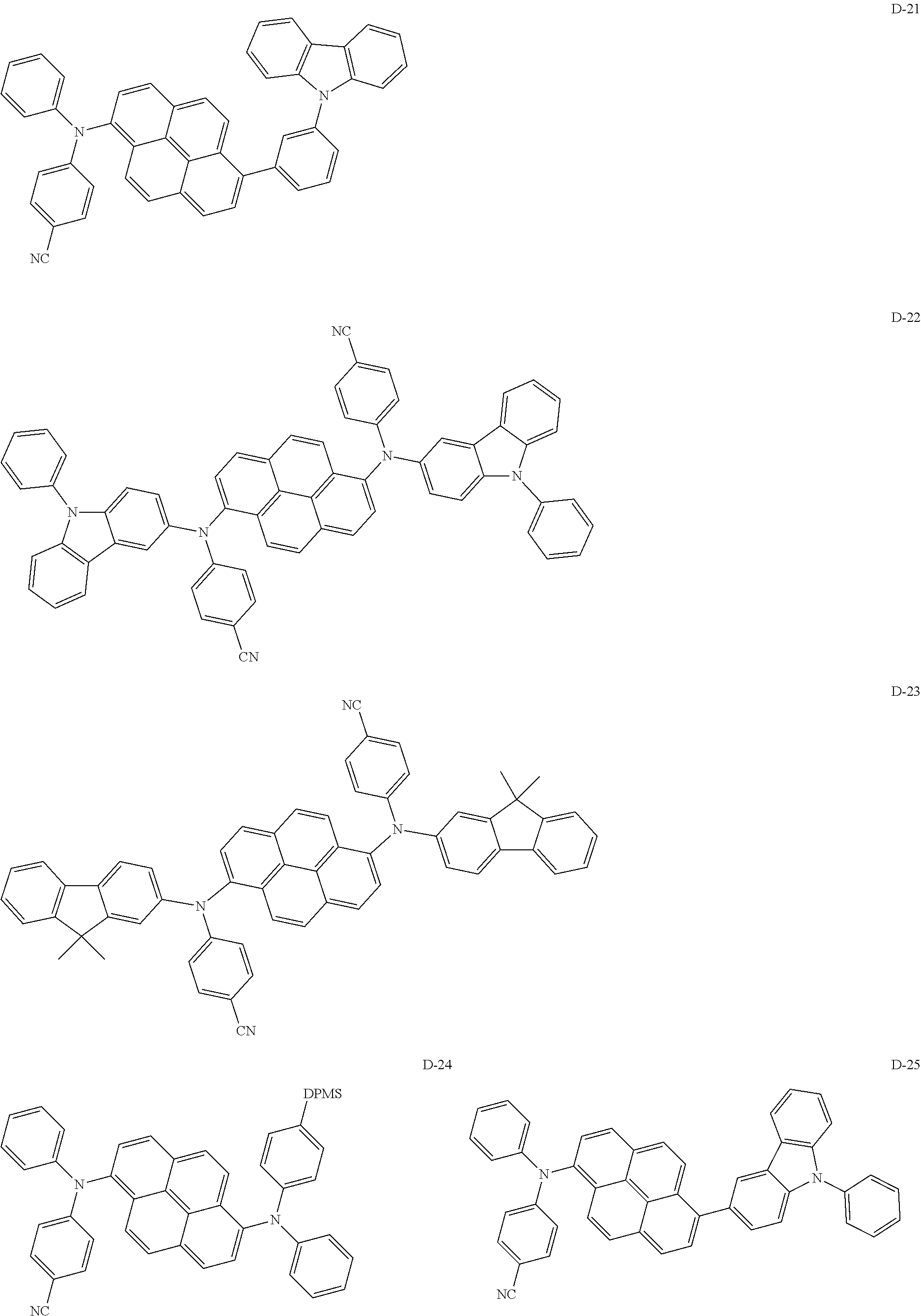 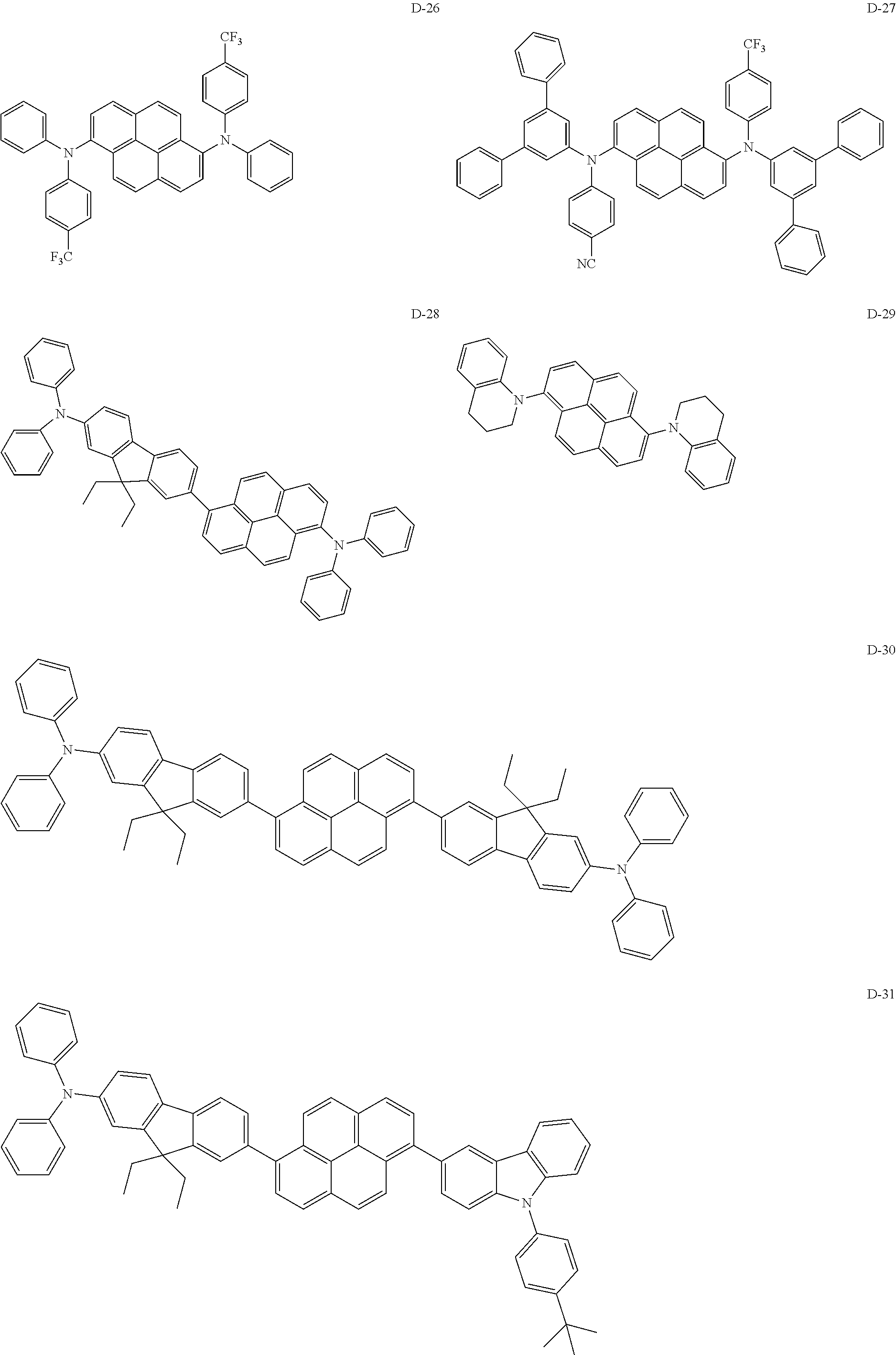 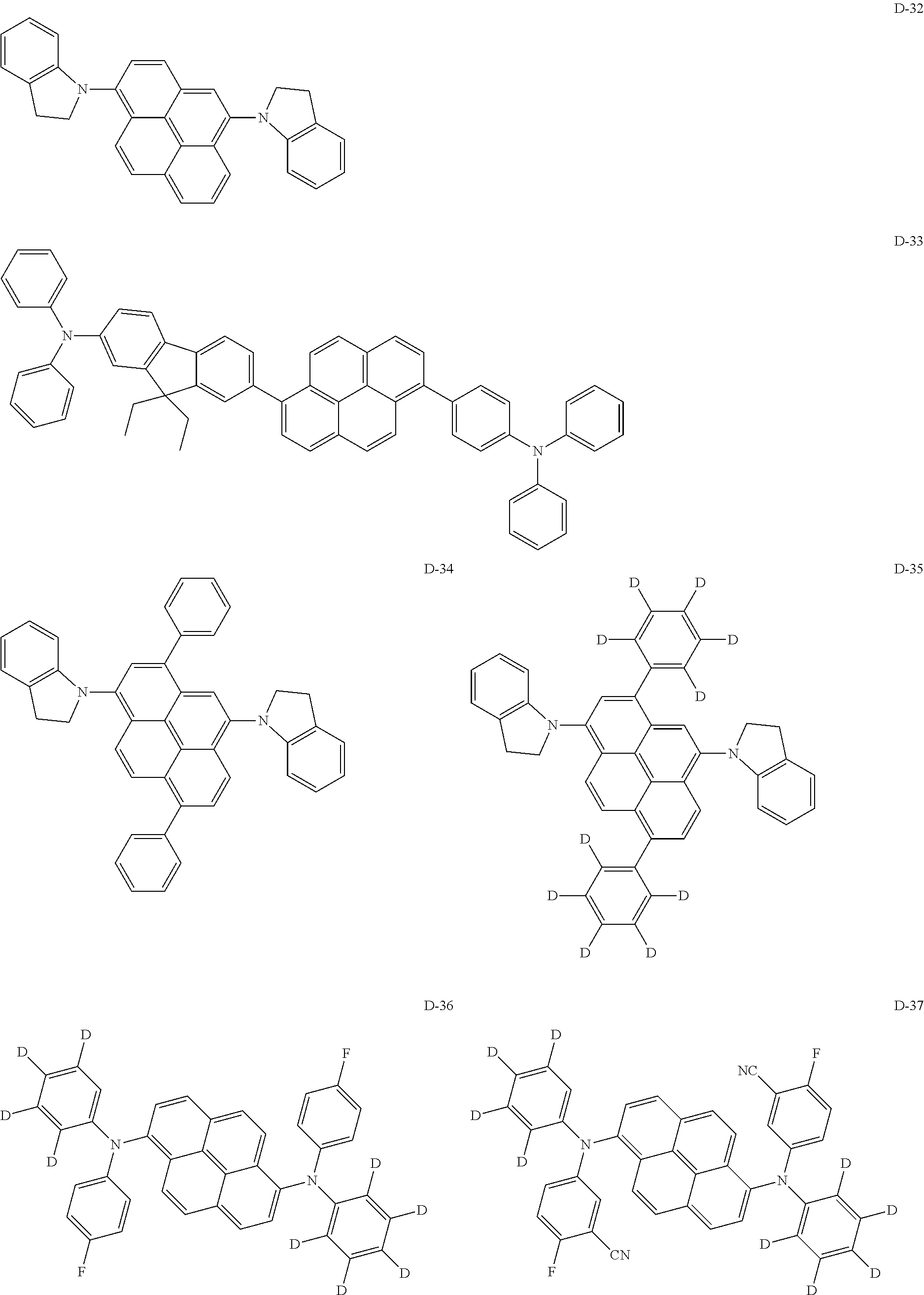 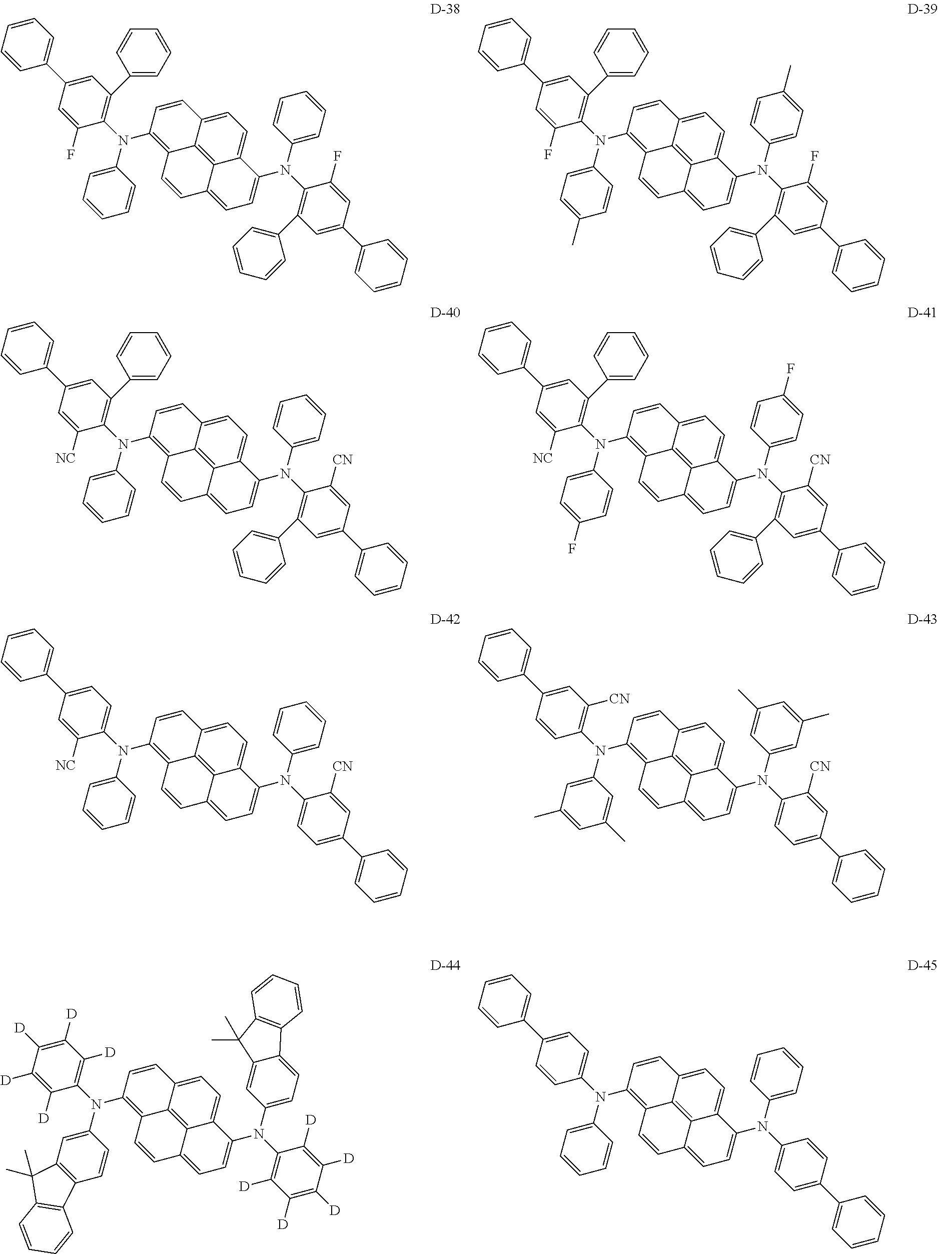 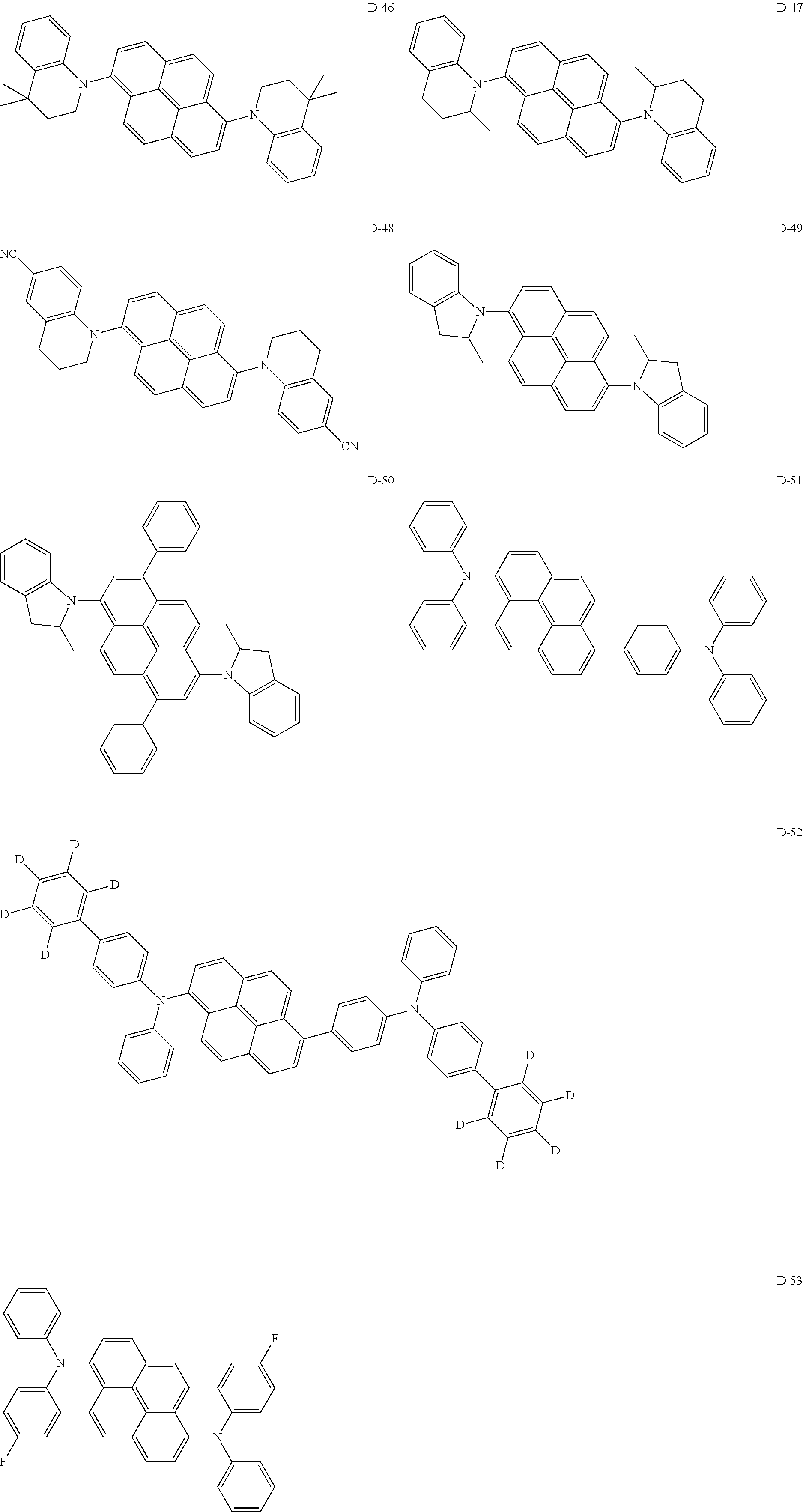 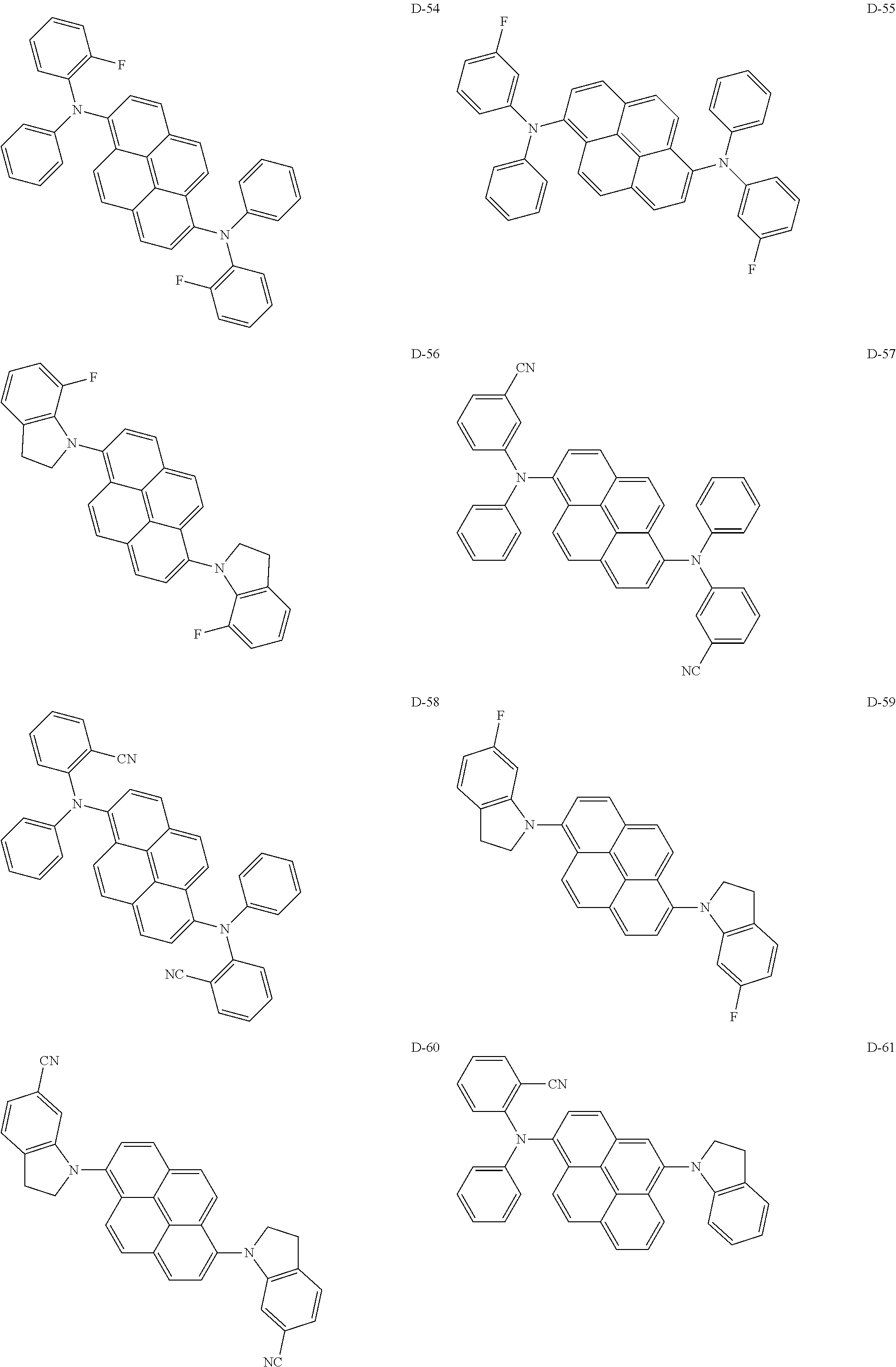 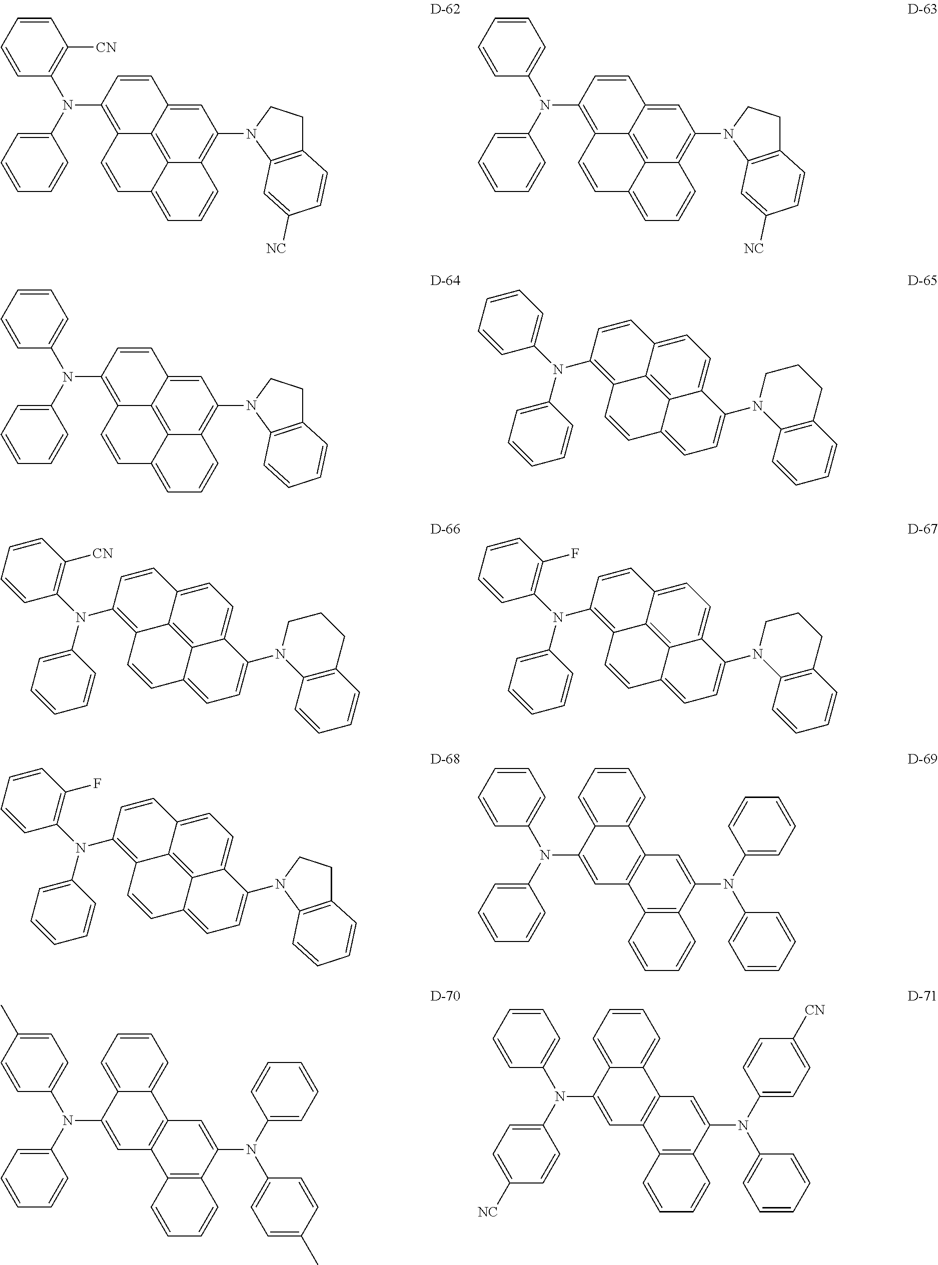 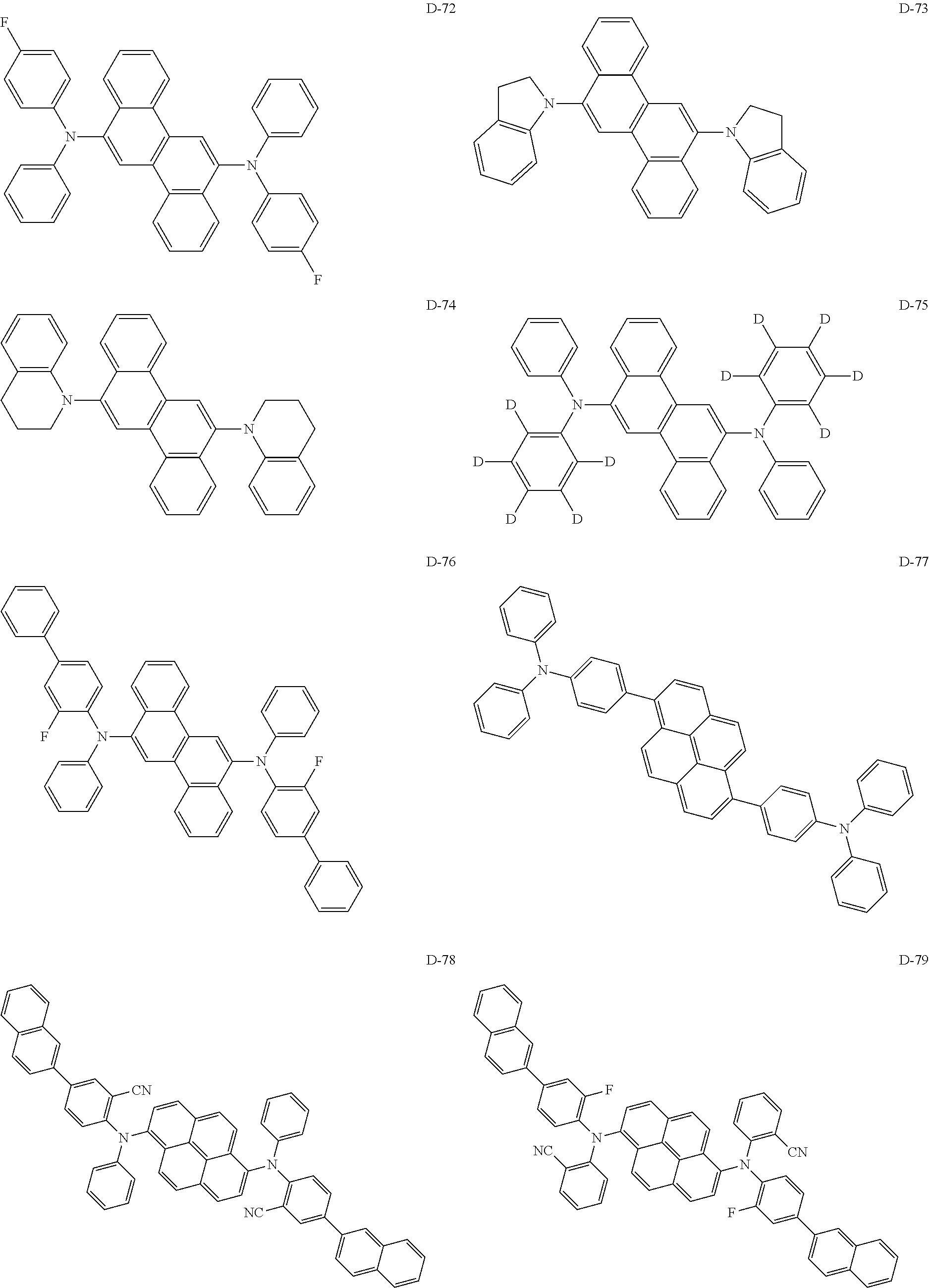 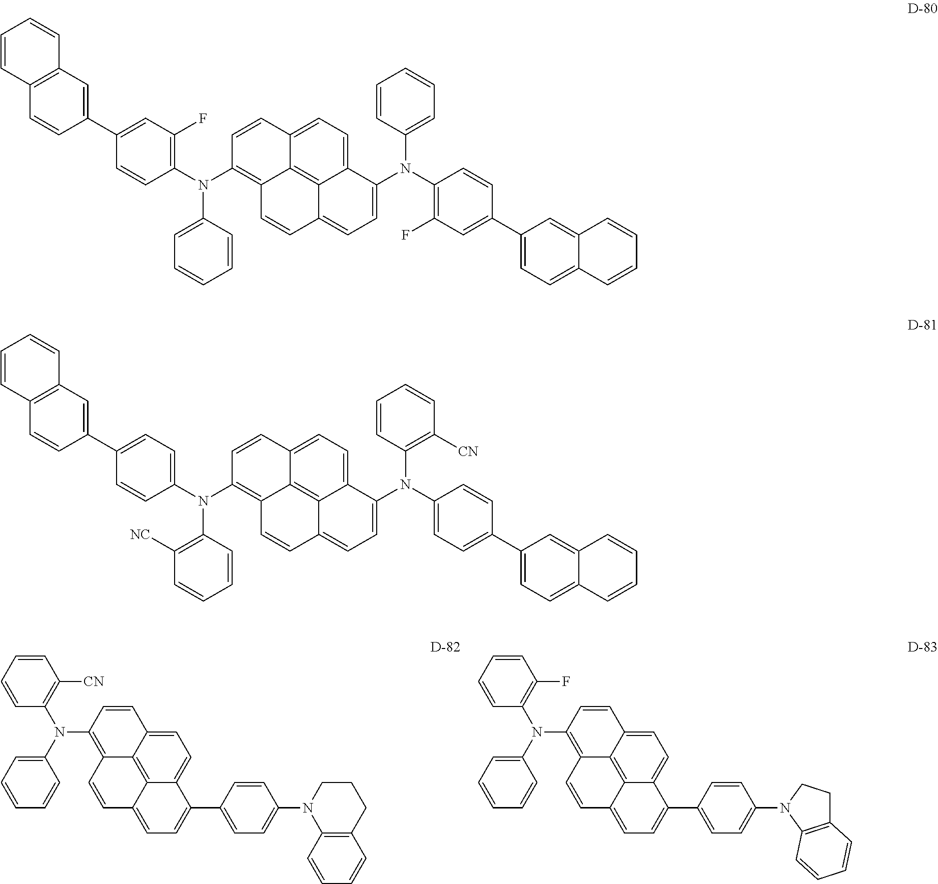 [SMILES: Fc1cc(-c2ccc3ccccc3c2)ccc1N(c1ccccc1)c1ccc2ccc3c(N(c4ccccc4)c4ccc(-c5ccc6ccccc6c5)cc4F)ccc4ccc1c2c43 ; N#Cc1ccccc1N(c1ccc(-c2ccc3ccccc3c2)cc1)c1ccc2ccc3c(N(c4ccc(-c5ccc6ccccc6c5)cc4)c4ccccc4C#N)ccc4ccc1c2c43 ; N#Cc1ccccc1N(c1ccccc1)c1ccc2ccc3c(-c4ccc(N5CCCc6ccccc65)cc4)ccc4ccc1c2c43 ; Fc1ccccc1N(c1ccccc1)c1ccc2ccc3c(-c4ccc(N5CCc6ccccc65)cc4)ccc4ccc1c2c43]
